(19) United States
(12) Patent Application Publication
(10) Pub. No.: US 2011/0250757 A1
(43) Pub. Date: Oct. 13, 2011

(54) METHOD OF MANUFACTURING SEMICONDUCTOR DEVICE

(75) Inventors: Mitsunari Sukekawa, Tokyo (JP); Hiromitsu Oshima, Tokyo (JP)

(73) Assignee: Elpida Memory, Inc., Tokyo (JP)

(21) Appl. No.: 13/083,083

(22) Filed: Apr. 8, 2011

(30) Foreign Application Priority Data
Apr. 9, 2010 (JP) 2010-090956
Apr. 6, 2011 (JP) 2011-084454

(51) Int. Cl. H01L 21/311

(52) U.S. Cl. 438/703; 257/E21.249

(57) ABSTRACT

A coating film is formed on a member to be etched, which includes an amorphous carbon film and a silicon oxynitride film, by a spin coating method; a sidewall core is formed by pattering the coating film; a silicon oxide film is formed to cover at least the side surface of the sidewall core; and an organic anti-reflection film is formed on the silicon oxide film by a spin coating method. Thereafter, an embedded mask is formed to cover concave portions of the silicon oxide film by etching the organic anti-reflection film; exposed is a portion of the member to be etched which does not overlap the sidewall core or the embedded mask by etching the silicon oxide film; and the member to be etched is etched. Thus, it is possible to obtain a pattern with a size less than the photolithography resolution limit.

### BACKGROUND OF THE INVENTION

1. Field of the Invention

The present invention relates to a method of manufacturing a semiconductor device, and more particularly relates to a method of manufacturing semiconductor device including a step of forming a fine pattern of a size smaller than the resolution limit of lithography by using a sidewall spacer as a mask.

2. Description of Related Art

Conventionally, a photolithography technique typically involved etching an underlying silicon substrate or a silicon oxide layer using a photoresist pattern as a mask obtained by exposure and development through a photomask. However, the type of light source used for exposure is changed with miniaturization and some types of light sources inevitably require use of photoresists with low etching resistance. Therefore, the following technique is frequently used recently for pattern formation. That is, a pattern is once transferred onto an underlying film, for example, a silicon nitride film, having a thickness that is relatively thin but thick enough to enable the photoresist to endure. Thereafter, a layer that originally needs to be processed, for example, a silicon oxide film, which is a film beneath the silicon nitride film, is etched using the silicon nitride film as a mask, thereby forming a pattern. A silicon nitride film patterned in this manner is called “hard mask”.

In recent years, demands for downsizing and higher density of semiconductor memories or the like have surpassed the speed of development of lithography techniques represented by, for example, exposure devices or photoresist materials. As a result, methods of forming a pattern of a size smaller than the resolution limit of lithography are drawing attention. For example, U.S. Pat. No. 7,550,391 discloses a technique of forming a fine pattern of a size smaller than the resolution limit of lithography by embedding a hard mask material into areas between sidewall spacers and removing the sidewall spacers by etching.

### SUMMARY

U.S. Pat. No. 7,550,391 discloses, as the material of the first and second mask patterns, a polycrystalline silicon film which can be buried even in a minute groove with a high aspect ratio and can be easily controlled to exhibit a high ratio in etching rate to another film such as a silicon oxide film. However, since the polycrystalline silicon film is formed at the relatively high temperature of 550° C., there occurs the problem that the film peels off due to the stress mainly in the interface between the hard mask layer and the member to be etched. When a silicon nitride film is used as a hard mask for patterning the amorphous carbon layer, the problem with the peeling may be more serious.

In one embodiment, there is provided a method of manufacturing a semiconductor device, comprising: forming a first coating film on a member to be etched; forming a sidewall core by patterning the first coating film; forming a first layer covering at least a side surface of the sidewall core; forming a second coating film on the first layer; forming an embedded mask covering a concave portion of the first layer by etching the second coating film; and exposing a portion of the member to be etched which does not overlap the sidewall core or the embedded mask by etching the first layer.

According to the invention, since the coating film is used as the material of the sidewall core and the embedded mask, it is possible to form the sidewall core or the embedded mask at a sufficiently low temperature. Thus, the peeling occurring in the related art rarely occurs in the interface between the hard mask layer and the member to be etched.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram showing an example of a memory cell array of a PRAM, which is an example of a semiconductor device suitable for applying a semiconductor device manufacturing method according to the present invention;

FIGS. 2A and 2B are side cross sectional views for schematically showing a configuration of a PRAM, where FIG. 2A is a cross sectional view taken along a direction of a word line WL, and FIG. 2B is a cross sectional view taken along a direction of a bit line BL;

FIGS. 3A to 5C are diagrams showing a manufacturing process of the exemplified PRAM, where FIGS. 3A, 4A, and 5A are plan views, FIGS. 3B, 4B, and 5B are cross sectional views taken along an arrow X-X of respective drawings, and FIGS. 3C, 4C, and 5C are cross sectional views taken along an arrow Y-Y of respective drawings;

FIGS. 6A to 31C are diagrams illustrating a process of manufacturing the semiconductor device according to a first embodiment of the invention, where FIGS. 6A, 8A, 10A, 12A, 14A, 16A, 18A, 20A, 22A, 24A, 26A, 28A, and 30A are plan views, FIGS. 6B, 8B, 10B, 12B, 14B, 16B, 18B, 20B, 22B, 24B, 26B, 28B, and 30B are cross sectional views taken along an arrow X-X of FIGS. 6A, 8A, 10A, 12A, 14A, 16A, 18A, 20A, 22A, 24A, 26A, 28A, and 30A, respectively, FIGS. 7A, 9A, 11A, 13A, 15A, 17A, 19A, 21A, 23A, 25A, 27A, 29A, and 31A are cross sectional views taken along an arrow Y1-Y1 of FIGS. 6A, 8A, 10A, 12A, 14A, 16A, 18A, 20A, 22A, 24A, 26A, 28A, and 30A, respectively, FIGS. 7B, 9B, 11B, 13B, 15B, 17B, 19B, 21B, 23B, 25B, 27B, 29B, and 31B are cross sectional views taken along an arrow Y2-Y2 of FIGS. 6A, 8A, 10A, 12A, 14A, 16A, 18A, 20A, 22A, 24A, 26A, 28A, and 30A, respectively, FIGS. 11C, 13C, 15C, 17C, 19C, 21C, 23C, 25C, 27C, 29C, and 31C are cross sectional views taken along an arrow Y3-Y3 of FIGS. 10A, 12A, 14A, 16A, 18A, 20A, 22A, 24A, 26A, 28A, and 30A, respectively;

FIGS. 32A to 35B are sectional views illustrating a process of manufacturing a semiconductor device according to a modified example of the first embodiment;

FIGS. 36A to 47C are diagrams illustrating a process of manufacturing the semiconductor device according to a second embodiment of the invention, where FIGS. 36A, 38A, 40A, 42A, 44A, and 46A are plan views, FIGS. 36B, 38B, 40B, 42B, 44B, and 46B are cross sectional view taken along arrow X-X of FIGS. 36A, 38A, 40A, 42A, 44A, and 46A, respectively, FIGS. 37A, 39A, 41A, 43A, 45A, and 47A are cross sectional views taken along an arrow Y1-Y1 of FIGS. 36A, 38A, 40A, 42A, 44A, and 46A, respectively, FIGS. 37B, 39B, 41B, 43B, 45B, and 47B are cross sectional views taken along an arrow Y2-Y2 of FIGS. 36A, 38A, 40A, 42A, 44A, and 46A, respectively, FIGS. 37C, 39C, 41C, 43C, 45C, and 47C are cross sectional views taken along an arrow Y3-Y3 of FIGS. 36A, 38A, 40A, 42A, 44A, and 46A, respectively;

FIGS. 48A to 54B are diagrams illustrating a process of manufacturing the semiconductor device according to a third embodiment of the invention, where FIGS. 48A, 49A, 50A, 51A, 52A, 53A, and 54A are plan views, FIGS. 48B, 49B, 50B, 51B, 52B, 53B, and 54B are cross sectional views taken along an arrow X2-X2 of respective drawings;

FIGS. 55 and 56 are plan views illustrating a process of manufacturing a semiconductor device according to a modified example of the third embodiment; and

FIG. 57 is a plan view illustrating a photo mask which is used in a process of manufacturing a semiconductor device according to a modified example of the third embodiment.

### DETAILED DESCRIPTION OF THE EMBODIMENTS

Preferred embodiments of the present invention will be explained below in detail with reference to the accompanying drawings. Further, the sizes of various portions illustrated in the accompanying drawings are arbitrarily scaled down or up, and thus the illustrations may not represent the actual or relative sizes.

A PRAM (Phase Change RAM) device is briefly explained first, as an example of a semiconductor device suitable for applying a manufacturing method according to the present invention.

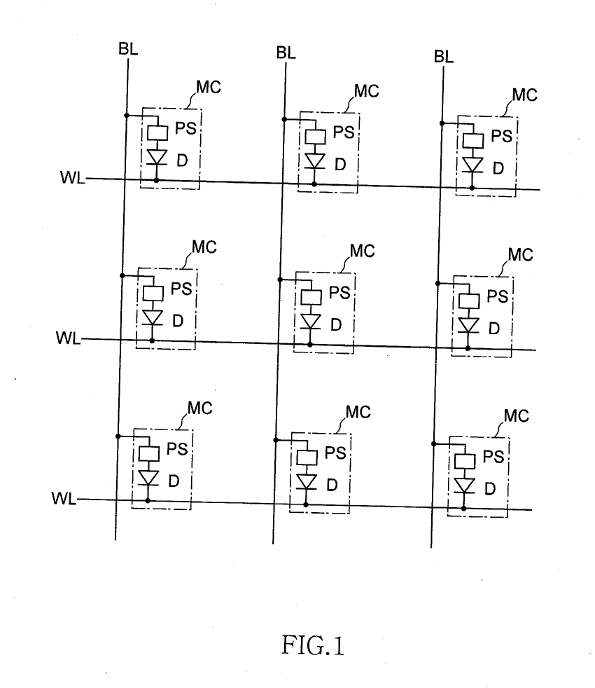

FIG. 1 is a circuit diagram showing an example of a memory cell array of a PRAM.

As shown in FIG. 1, the memory cell array of the PRAM includes a plurality of word lines WL and a plurality of bit lines BL. The word lines WL and the bit lines BL orthogonally intersect with each other and a memory cell MC is provided at each node. Each of the memory cells MC includes a series circuit formed of a phase-change material device PS and a diode D. One end of the phase-change material device PS is connected to a corresponding bit line BL while one end of the diode D is connected to a corresponding word line WL.

The phase-change material device PS can have two stable states that have different electrical resistances and can make a mutually reversible transition therebetween. By detecting the electrical resistances of the phase-change material device PS, programmed information can be read. When the memory cell MC is not selected, the diode D is reverse-biased and controlled to be in a non-conductive state. When the memory cell MC is selected, the diode D is controlled to be in a conductive state by controlling the corresponding bit line BL to a high potential and the corresponding word line WL to a low potential. As a result, the electrical resistances of the phase-change material device PS are detected by causing a current to flow through the phase-change material device PS.

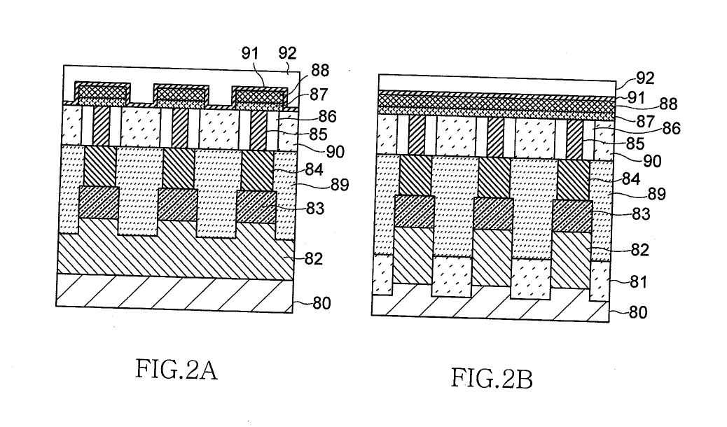

FIGS. 2A and 2B are side cross sectional views of the PRAM memory cell, respectively taken along a direction of a word line WL and a bit line BL. FIGS. 2A and 2B respectively show a three-bit memory cell.

As shown in FIGS. 2A and 2B, an N-type impurity diffusion layer 82 formed on a P-type silicon substrate 80 forms the word lines WL. Adjacent word lines WL are isolated from each other by a silicon oxide layer 81. The N-type impurity diffusion layer 82 and a P-type impurity diffusion layer 83 are formed on silicon pillars, which are formed on the silicon substrate 80 and isolated from each other by an insulating layer 89, and constitute the diodes D. A phase-change material layer 87 is sandwiched between heater electrodes 85 and upper electrodes 88 and constitutes the phase-change material devices PS. The phase-change material layer 87 is connected to each of the diodes D in a series via a metal plug 84. The upper electrode 88 extends in a direction orthogonal to the word lines WL and functions as the bit lines BL that are commonly connected to a plurality of memory cells. The phase-change material layer 87 is covered with an interlayer insulating film 92 via an anti-deterioration protective insulating film 91. The heater electrode 85 is formed with a diameter restricted to be small by an insulating layer 86 formed on inner walls of an opening formed in an insulating layer 90, thus realizing a high current density.

A manufacturing process of the exemplified PRAM is briefly explained below.

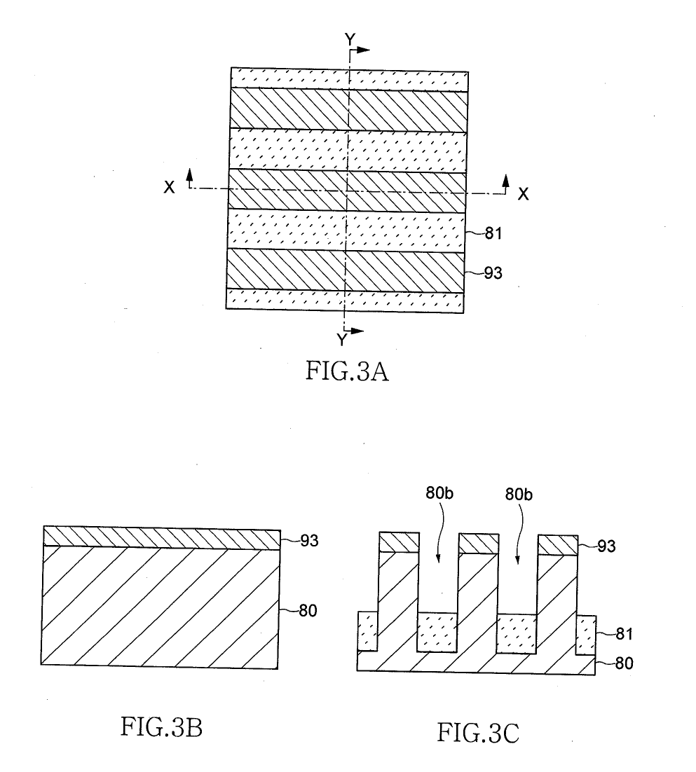

FIGS. 3A to 5C show manufacturing processes of the exemplified PRAM, where FIGS. 3A, 4A, and 5A are plan views, FIGS. 3B, 4B, and 5B are cross sectional views taken along an arrow X-X of respective drawings, and FIGS. 3C, 4C, and 5C are cross sectional views taken along an arrow Y-Y of respective drawings.

In manufacturing a PRAM, a P-type silicon substrate is prepared first. Thereafter, as shown in FIGS. 3A to 3C, isolation trenches 80b extending in a Y direction (Extending direction of the word lines WL) are formed by etching the silicon substrate 80 for 200 nanometers (nm) using an amorphous carbon hard mask 93. In a plane pattern of the amorphous carbon hard mask 93 that forms the isolation trenches 80b, space patterns (light pattern portions) extending in the X direction and having a width of 25 nm, are arranged at a pitch of 50 nm in an Y direction (Extending direction of the bit lines BL). Accordingly, the isolation trenches 80b can be formed on a surface of the silicon substrate 80 in a memory cell array area. On the other hand, no trench is formed in a peripheral circuit area (not shown) other than the memory cell array area except for a positioning monitor mark or the like. Thus the surface of the silicon substrate 80 is covered with the amorphous carbon hard mask 93, forming a dark pattern portion.

Next, a thick silicon oxide layer is formed using a CVD method to fill the isolation trenches 80b. Thereafter, the thick silicon oxide layer is etched back to form the silicon oxide layer 81 for isolating the word lines WL.

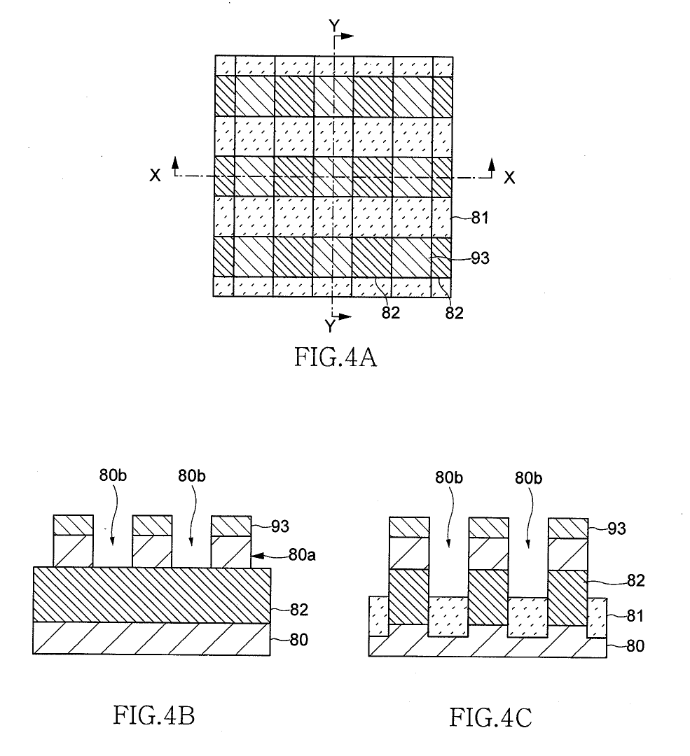

Next, a hard mask pattern is formed in which the space patterns, which are orthogonal to the isolation trenches 80b, extend in the Y direction and have a width of 25 nm, are arranged at a pitch of 50 nm in the Y direction. The amorphous carbon hard mask 93 is etched using the hard mask pattern and an amorphous carbon hard mask pattern array of island-shape having a size of 30 nm×30 nm is obtained as shown in FIGS. 4A to 4C. Silicon pillars 80a are formed by etching the silicon substrate 80 by, for example, 100 nm using the amorphous carbon hard mask 93.

N-type impurities such as phosphorus are then ion-implanted into the silicon substrate 80. The phosphorus implanted into the surface of the silicon substrate 80 to which a bottom of each trench is exposed is activated by heat treatment performed after the ion-implantation, and diffused in the silicon substrate 80 to reach an area below the silicon pillars 80a. As a result, the N-type impurity diffusion layer 82, that is, the word line WL extending in the X direction, is formed.

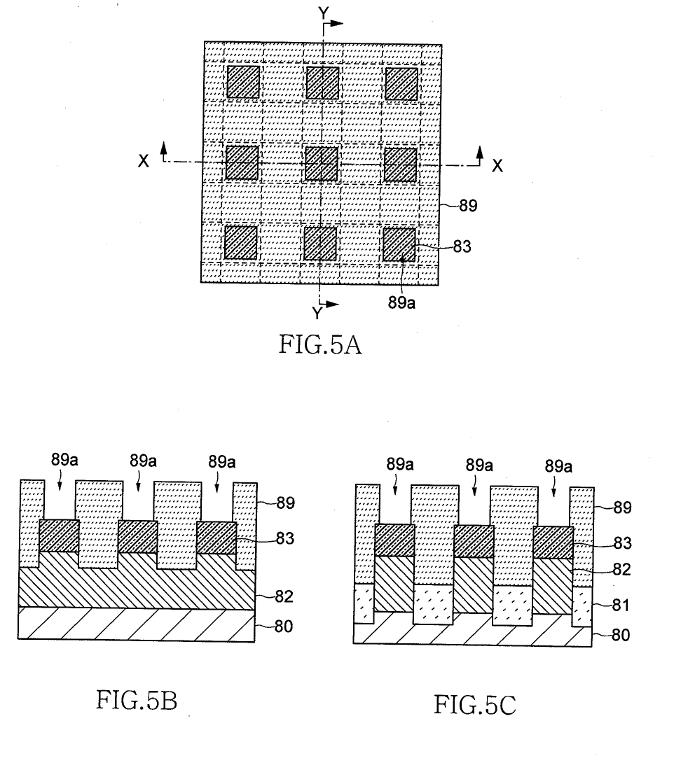

Next, as shown in FIGS. 5A to 5C, openings 89a for metal plugs are formed after the insulating layer 89 is formed on the surface of the silicon substrate 80. The P-type impurity diffusion layer 83 is formed by introducing P-type impurities in the silicon pillars 80a, and as a result, PN diodes D are formed. A plane pattern of the hard mask, which is used for forming the openings 89a, having a size of, for example, 24 nm×24 nm is arranged at pitches of 50 nm in the X direction and the Y direction. The pitches and intervals between respective adjacent opening portions are uniform in both the X direction and the Y direction. In a peripheral circuit area other than the memory cell array area, no opening portion is formed except for a positioning monitor or the like mark is formed, and thus the surface of the silicon substrate 80 is covered with the hard mask, forming a dark pattern portion.

Subsequent steps are not shown in the drawings; however, after sequentially forming the metal plugs 84, the heater electrodes 85, the phase-change material layer 87, and the upper electrodes 88, similarly to a general semiconductor device, an interlayer insulating film, metal wiring or the like are formed to complete the PRAM shown in FIGS. 2A and 2B.

The upper electrodes 88 formed in the memory cell array region are formed by arranging a line pattern which has a width of 25 nm and extends in the Y direction at a pitch of 50 nm in the X direction. On the other hand, formed is a sparser pattern, such as an alignment monitor mark or a peripheral circuit wiring pattern, which has an arbitrary size and an arbitrary shape, in the peripheral circuit region other than the memory cell array region.

Next, a method of manufacturing the semiconductor device according to the invention will be described in more detail, and particularly, a method of processing the upper electrodes 88 using a hard mask will be described in more detail.

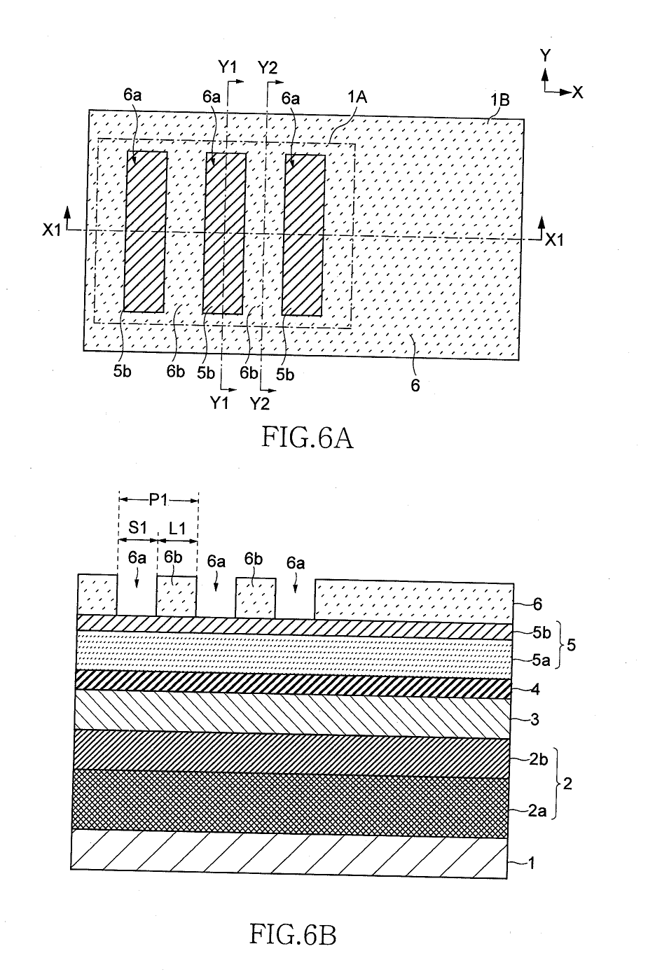

FIGS. 6A to 19C are diagrams illustrating a process of manufacturing the semiconductor device according to a first embodiment of the invention. Hereinafter, a process of forming the upper electrodes 88 will first be described in the process of manufacturing the PRAM exemplified above.

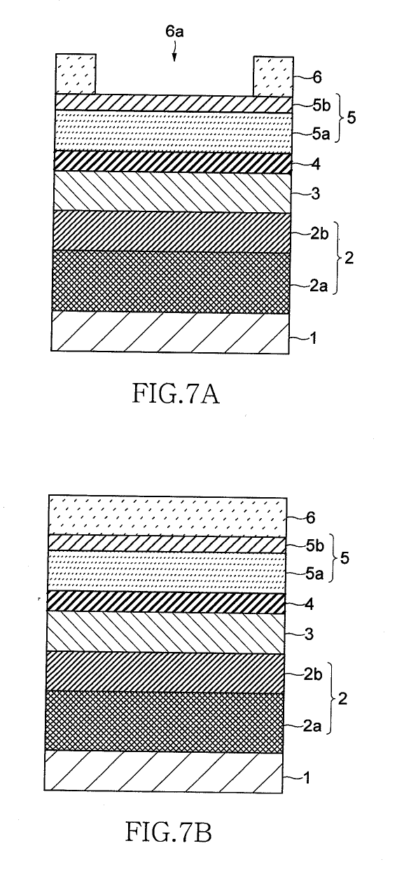

In the process of manufacturing the semiconductor device according to this embodiment, first, a wiring layer 2, an amorphous carbon film 3, a silicon oxynitride film 4, and a coating film 5 are sequentially formed on a silicon substrate 1, as shown in FIGS. 6A and 6B and FIGS. 7A and 7B. In this embodiment, the silicon substrate 1 is not a non-processed silicon substrate but a substrate which includes respective functional layers such as an impurity diffusion layer, an insulation film, and a metal film.

The wiring layer 2 is a layer in which the upper electrodes 88 are processed and is formed by sequentially laminating a tungsten film 2a serving as a conductive film and a silicon nitride film 2b serving as a protective film of the conductive film. The thickness of the silicon nitride film 2b is 200 nm. The material of the conductive film is not limited to tungsten, but titanium nitride, aluminum, doped silicon, or the like may be used. The protective film is not limited to the silicon nitride film 2b, but protective film may not be formed depending on a conductive film, if necessary.

The amorphous carbon film 3 is a lower hard mask material used for patterning the wiring layer 2 and has a thickness of 200 nm. The amorphous carbon film 3 has an advantage of improving the degree of freedom of a material to be etched in that the amorphous carbon film 3 is excellent in etching resistance as a hard mask. Moreover, the amorphous carbon film 3 is a film which can be removed by ashing and is advantageous since the amorphous carbon film can be removed without causing damage to a substrate or a wiring after the material to be etched is etched.

The silicon oxynitride film 4 is an upper hard mask material used for patterning the amorphous carbon film 3 and has a thickness of 30 nm. The silicon oxynitride film 4 can be formed by a CVD method. The hard mask material functions as a protective film protecting the surface of the amorphous carbon film 3 without causing damage and functions as an upper hard mask used for etching the amorphous carbon film 3.

The coating film 5 becomes a core pattern (sidewall core) when a sidewall spacer is formed. The coating film 5 is a two-layered film formed by sequentially laminating an organic anti-reflection film 5a and a silicon-containing organic film 5b. The organic anti-reflection film 5a has a role of controlling the reflection ratio of the surface of an underlying layer. Moreover, the organic anti-reflection film 5a is used as a function enhancement material which is used for planarizing the surface when a concave portion of the underlying layer is buried and is used as a mask when the underlying layer is etched. The silicon-containing organic film 5b is a film used for enhancing etching resistance when a photoresist is used as a mask and has a silicon content of, for example, 40%. The thickness of the organic anti-reflection film 5a is 200 nm and the thickness of the silicon-containing organic film 5b is nm. The organic anti-reflection film 5a and the silicon-containing organic film 5b can be formed in a temperature range from the normal temperature to 200° C. by a spin coating method.

Thereafter, a resist pattern 6 is formed to pattern the coating film 5. For example, the resist pattern 6 is formed by forming an ArF photoresist film by a spin coating method and then patterning the photoresist film using an ArF liquid immersion exposure apparatus. As in the coating film 5, the photoresist film can be formed in a temperature range of from the normal temperature to about 200° C.

The resist pattern 6 according to this embodiment has a plurality (herein, three) of thin and long openings 6a formed in the memory cell array region (first region) 1A. The opening 6a is used for forming a sidewall spacer necessary in forming a minute line-and-space pattern with a size less than a lithography resolution limit. For example, when the minimum processing size F of photolithography is equal to 50 nm, it is assumed that an interval (line width) L1 of the openings 6a is equal to 50 nm and the width (space width) S1 of the opening 6a is equal to 50 nm. The openings 6a all have the same width and are arranged at a pitch in the X direction. Accordingly, the openings 6a and resist line patterns 6b are alternately formed in the X direction, and thus the line-and-space pattern is formed.

The width of the opening 6a is preferably not too, broad. The reason for this is as follows. That is, an embedded mask pattern described below is formed as a coating film in the groove of a silicon oxide film formed based on the opening 6a. Therefore, a coating liquid is not sufficiently gathered when the width of the opening 6a is broad. As a consequence, since the film thickness of the embedded mask pattern is not sufficient, there may occur a problem that the surface of the underlying layer is etched unintentionally.

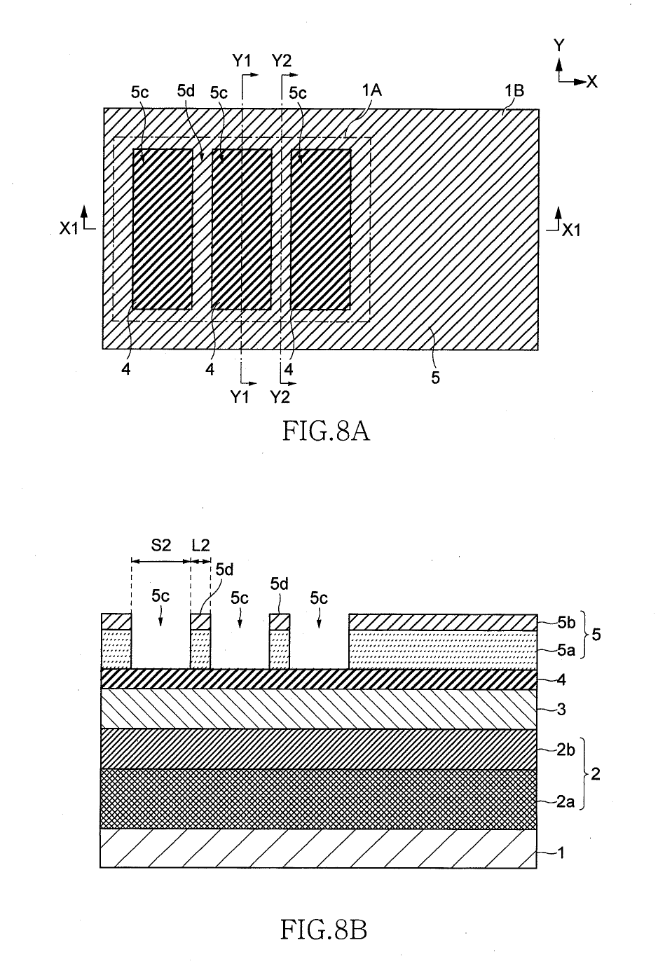

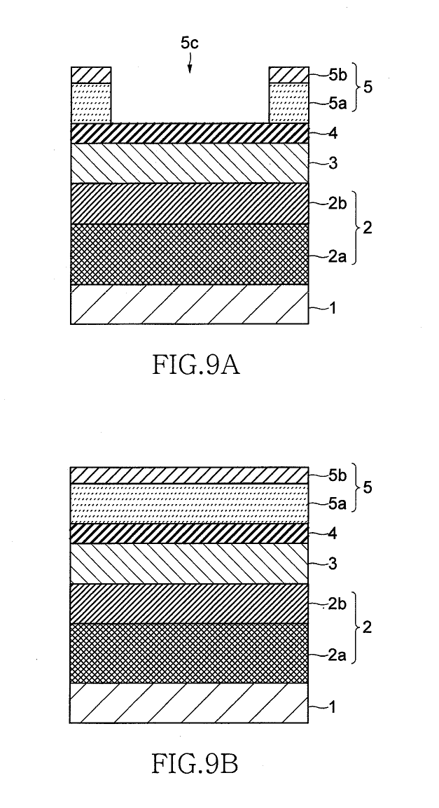

Subsequently, as shown in FIGS. 8A and 8B and FIGS. 9A and 9B, the resist pattern 6 is transferred onto the coating film 5 by subjecting the coating film 5 to anisotropic etching using the resist pattern 6 as a mask. The etching is performed under the condition that selectivity is obtained with respect to the silicon oxynitride film 4. The etching is performed by removing the silicon-containing organic film 5b and the organic anti-reflection film 5a using an etching gas including oxygen (O₂) and carbon monoxide (CO) and then removing residues using an etching gas including hydrogen (H₂) and nitrogen (N₂). Thus, an opening 5c is formed below the opening 6a so as to be penetrated through the organic anti-reflection film 5a and the silicon-containing organic film 5b, and thus the Surface of the silicon oxynitride film 4 is exposed.

In the etching of the coating film 5, a slimming process is also performed to uniformly retreat the sidewalls of the openings 5c of the coating film 5. Here, the sidewalls of the coating film 5 are retreated by 12.5 nm so that a pattern with a line width L1=50 nm and a space width S1=50 nm is changed into a pattern with a line width L2=25 nm and a space width S2=75 nm. The reason for controlling the ratio of the line width to the space width of “L2:S2=1:3” is to form sidewall spacers with a thickness of about 25 nm in the inner surface of the openings 5c with a width of 75 nm in a subsequent process and allow the interval of the adjacent sidewall spacers to be about 25 nm.

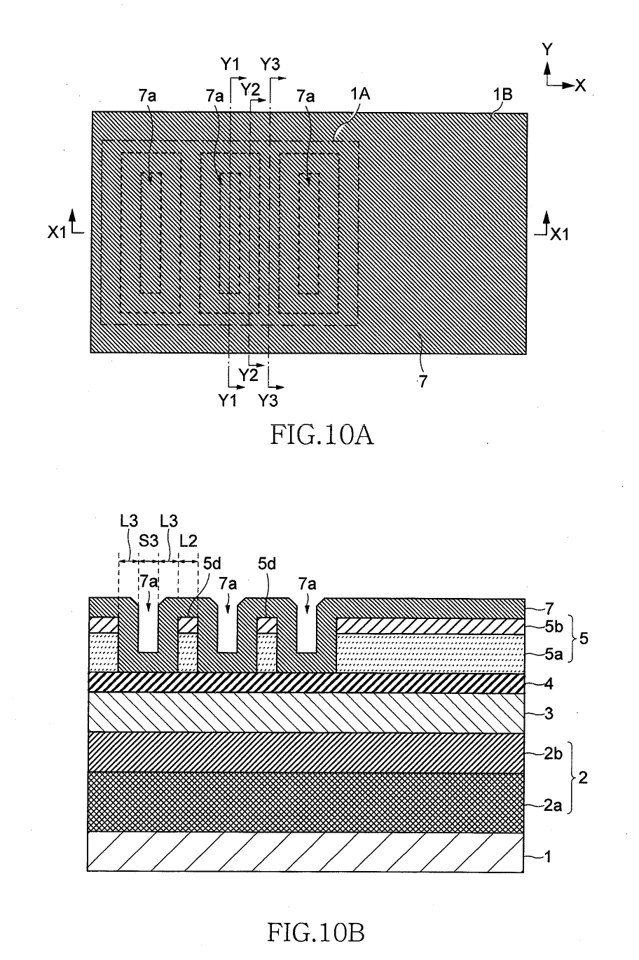

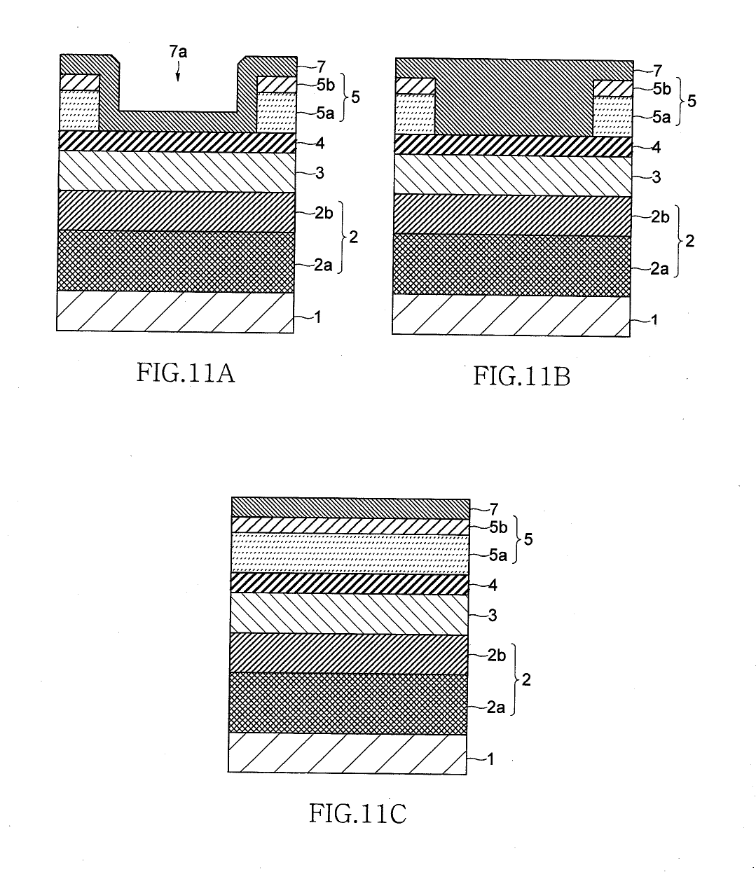

Next, as shown in FIGS. 10A and 10B and FIGS. 11A to 11C, a conformal sacrificial layer such as a silicon oxide film 7 is uniformly formed on the coating film 5 including the openings 5c. The silicon oxide film 7 is used for forming a minute pattern with a size less than the lithography resolution limit. The silicon oxide film 7 is formed at a temperature lower than the heat-resistant temperature of the organic anti-reflection film 5a and the silicon-containing organic film 5b, and is formed so that step coverage is good for the step difference of the openings 5c. The silicon oxide film 7 according to the embodiment is formed at a temperature equal to or less than 200° C. by an atomic layer deposition (ALD) and is preferably formed at a temperature equal to or less than 50° C. Moreover, the sacrificial film is not limited to the silicon oxide film. Any film which can be formed at a low temperature equal to or less than 200° C., has good step coverage and can make it possible to obtain etching selectivity with respect to an organic film can be used as the sacrificial film.

The silicon oxide film 7 is formed so as to have a thickness to the degree that the openings 5c are not completely embedded. The silicon oxide film 7 formed on the sidewall of the opening 5c is set to have a thickness L3=25 nm (=the line width L2 of the sidewall core) so that each concave portion 7a of the silicon oxide film 7 with a width S3=25 nm is formed in each opening 5c of the coating film 5. That is, the width L2 of the sidewall core 5d formed by the coating film 5, the width L3 of the sidewall spacer formed by the silicon oxide film 7, and the width S3 of the concave portion 7a formed after embedding the silicon oxide film 7 are the same as each other.

When forming a pattern having a size less than the lithography resolution limit according the related art, the sidewall spacer is formed by uniformly etching back the silicon oxide film 7. And then a mask pattern having a size less than the lithography resolution limit is formed using the sidewall spacer as a mask, and an underlying layer is patterned using the minute mask pattern. In this embodiment, by contrast, the silicon oxide film 7 is not immediately etched back. Instead, the silicon oxide film 7 is etched after the organic anti-reflection film 8 described below is embedded. Therefore, the silicon oxide film 7 is not processed as a separate sidewall spacer. In this embodiment, however, a portion of the silicon oxide film 7 which serves as the sidewall spacer when the silicon oxide film 7 is etched back, that is, a portion of the silicon oxide film 7 covering the side surface of the core pattern is called a sidewall spacer.

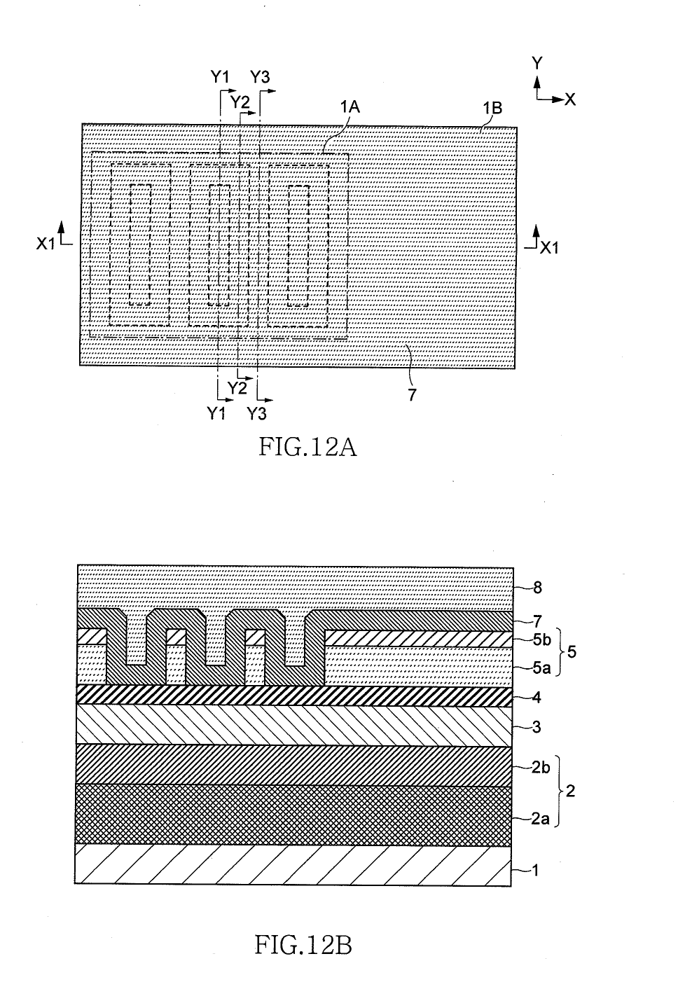

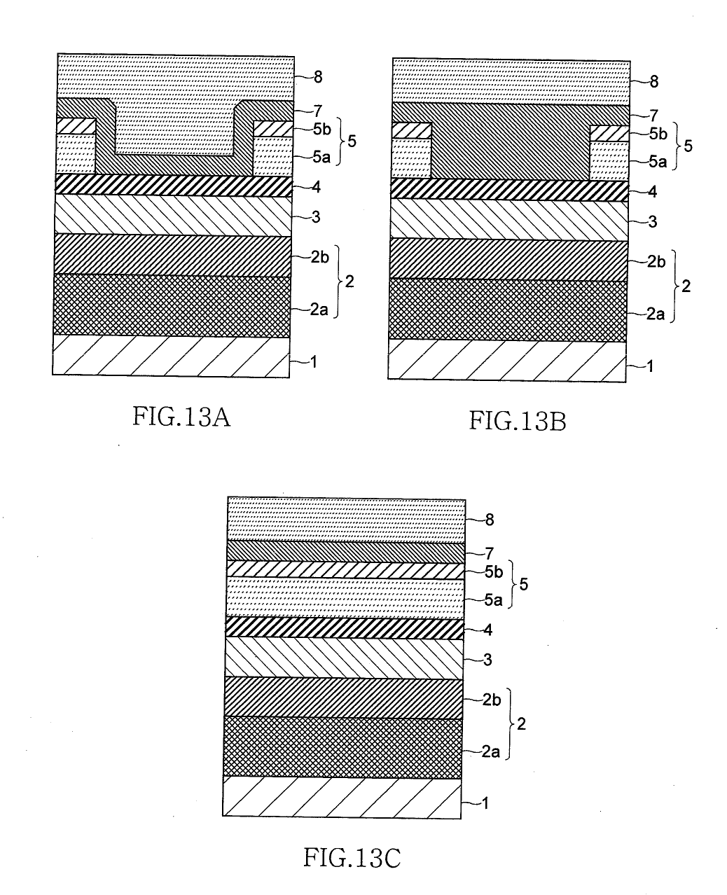

Next, as shown in FIGS. 12A and 12B and FIGS. 13A to 13C, the organic anti-reflection film 8 is formed on the silicon oxide film 7 so that the organic anti-reflection film 8 can be embedded in each concave portion 7a of the silicon oxide film 7. The thickness f the organic anti-reflection film 8 is not particularly limited, as long as the organic anti-reflection film 8 can completely be embedded in each concave portion 7a. For example, the thickness of the organic anti-reflection film 8 is 100 nm. A material used for burying each concave portion 7a is not limited to the organic anti-reflection film, but a resist film or the like may be used. However, a material with good flatness is preferably used so that the flatness is not damaged in a depressed portion of the concave portion 7a. The organic anti-reflection film 8 can be formed within a temperature range from the normal temperature to about 200° C. by a spin coating method. However, it is necessary to form the organic anti-reflection film 8 at a temperature lower than the heat-resistant temperature of the organic anti-reflection film 5a and the silicon-containing organic film 5b of the underlying layer.

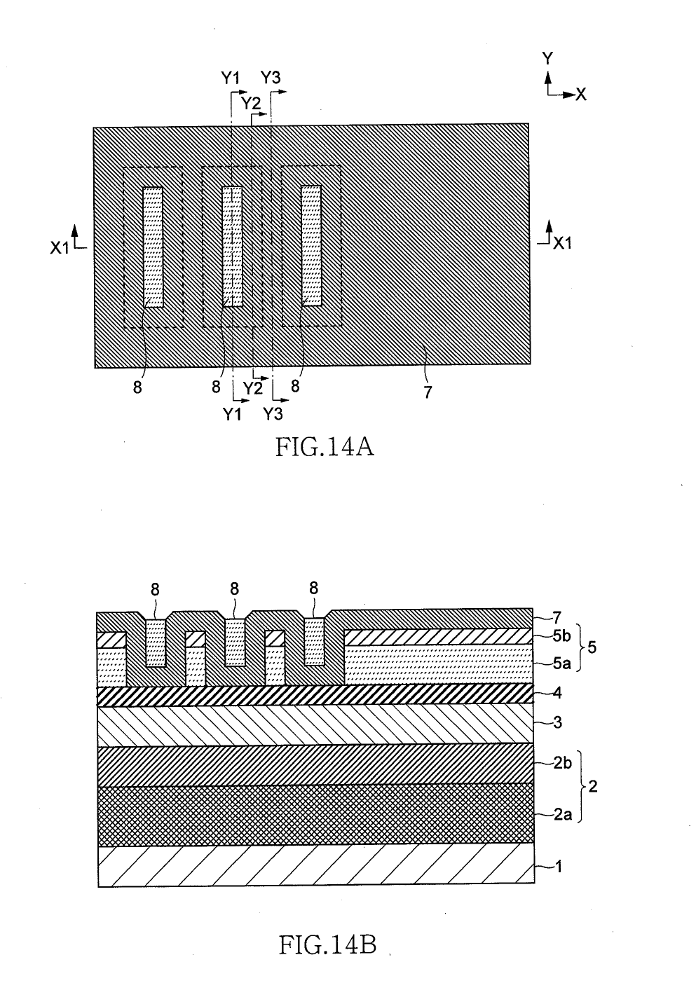

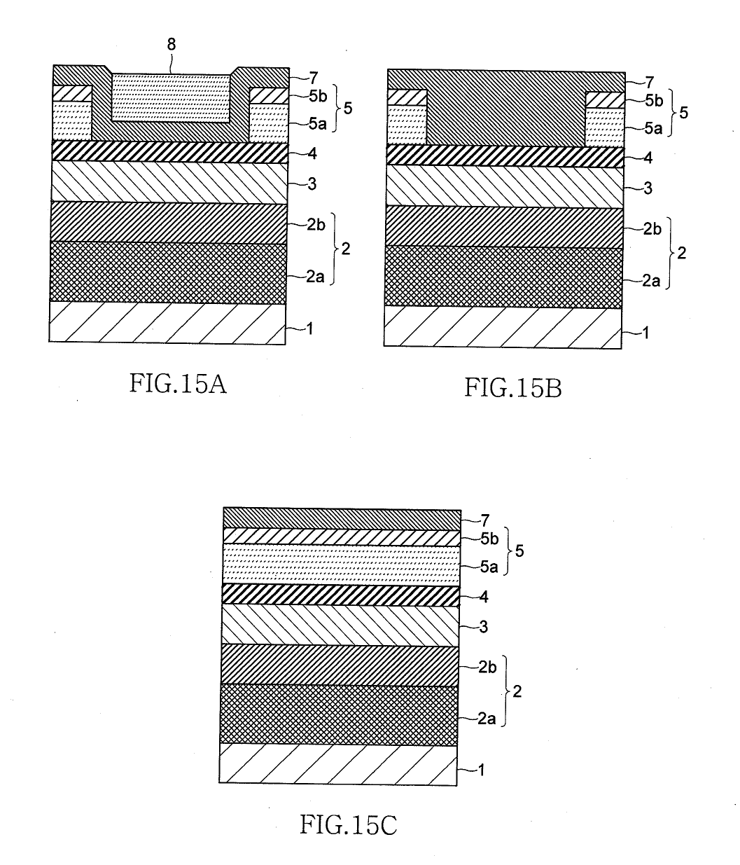

Next, as shown in FIGS. 14A and 14B and FIGS. 15A to 15C, the organic anti-reflection film 8 is made to remain only in the concave portions 7a of the silicon oxide film 7 by etching back the organic anti-reflection film 8 on the silicon oxide film 7. A gas including oxygen (O₂) and carbon monoxide (CO) can be used as an etching gas. Since the organic anti-reflection film 8 is embedded across the entire width of each concave portion 7a in the width direction (X direction), the width of the embedded mask pattern of the organic anti-reflection film 8 in the X direction is the same as the width of the concave portion 7a. As described above, when the flatness of the organic anti-reflection film 8 is good, the heights of the embedded mask patterns formed in the respective concave portions 7a are the same as each other, thereby forming a uniform pattern on a wafer surface.

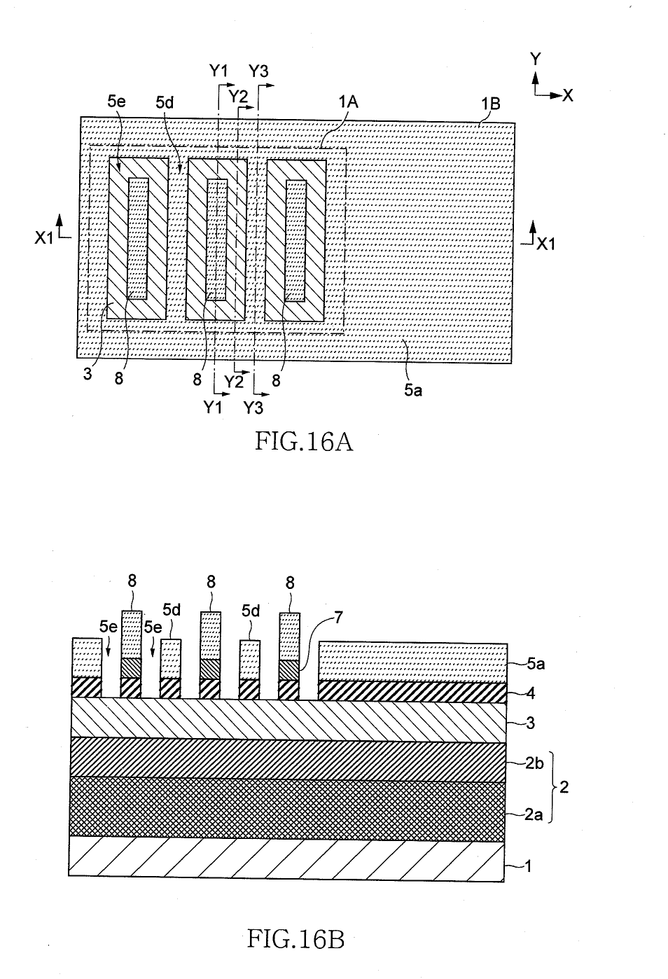

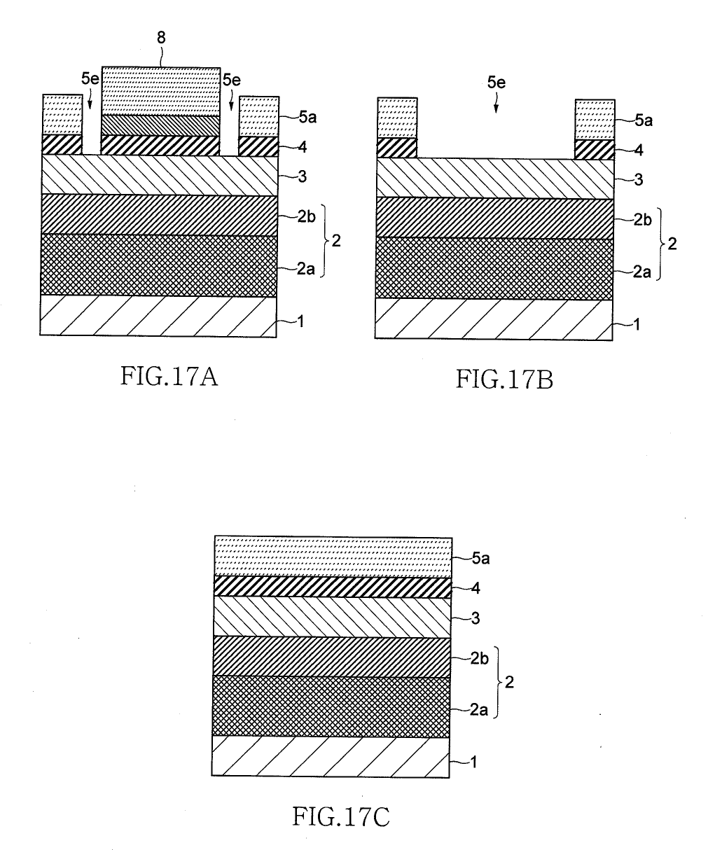

Next, as shown in FIGS. 16A and 16B and FIGS. 17A to 17C, the sidewall spacer of the silicon oxide film 7 exposed from each opening is removed by anisotropic etching. The etching is performed under the condition that etching selectivity is obtained with respect to the organic anti-reflection film 8 and the organic anti-reflection film 5a. A gas including carbon tetrafluoride (CF₄), carbon monoxide (CO), and argon (Ar) can be used as the etching gas. By this etching, the silicon-containing organic film 5b is removed and the silicon oxynitride film 4 directly below the sidewall spacers is also removed together with the silicon oxide film 7. Therefore, the surface of the amorphous carbon film 3 is exposed. Since the organic anti-reflection film 8 is embedded in each concave portion 7a of the silicon oxide film 7, the silicon oxide film 7 and the silicon oxynitride film 4 directly below the organic anti-reflection film 8 are not removed and only the sidewall spacers and the exposed upper surface are removed. According to the patterning method, width precision can be improved compared to a case where the sidewall spacers are actually formed by etching back the silicon oxide film 7.

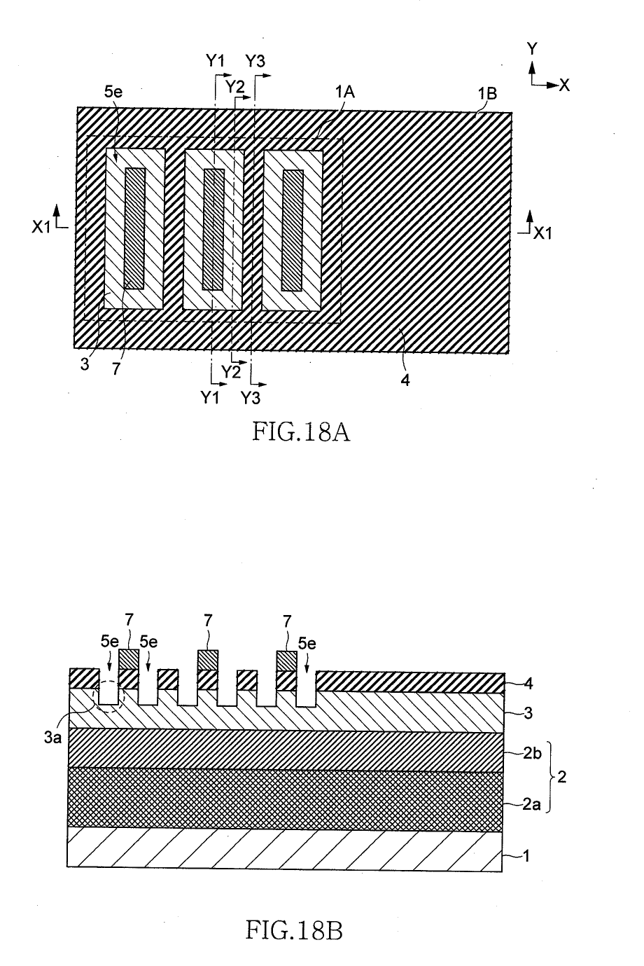

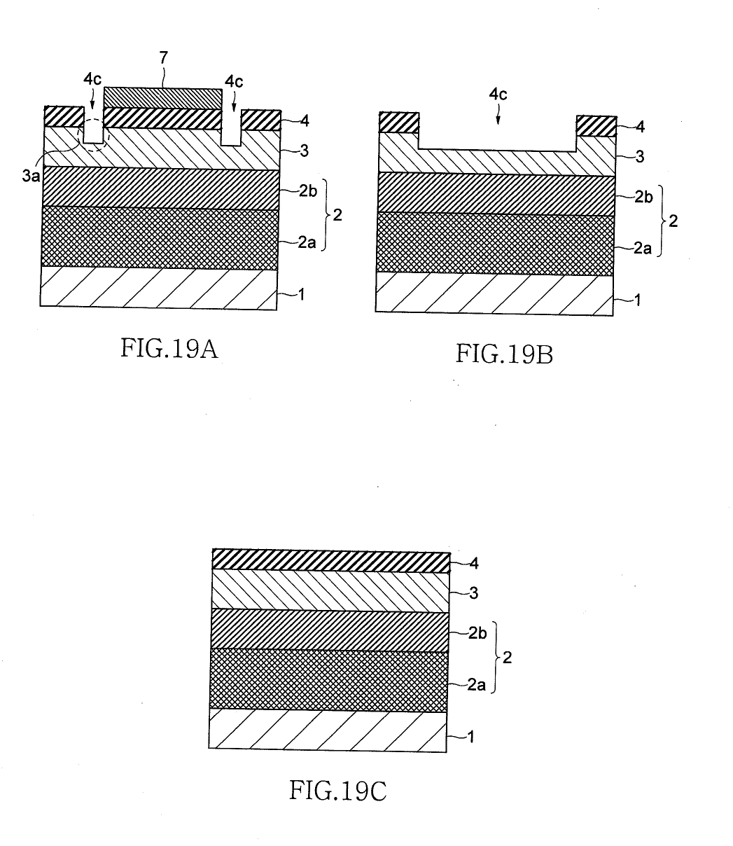

Next, as shown in FIGS. 18A and 18B and FIGS. 19A to 19C, the organic anti-reflection film 8 and the organic anti-reflection film 5a are removed by anisotropic etching and the silicon oxynitride film 4 is exposed. The etching is performed under the condition that etching selectivity is obtained with respect to the silicon oxynitride film 4. A gas including hydrogen (H₂) and nitrogen (N₂) can be used as the etching gas. At this time, the silicon oxide film directly below the organic anti-reflection film 8 remains without being removed. The surface of the amorphous carbon film 3 exposed from each concave portion 5e is etched together, and thus each concave portion 3a is formed on the exposed surface of the amorphous carbon film 3, as illustrated.

The sidewall surface of each concave portion 3a formed on the exposed surface of the amorphous carbon film 3 is preferably vertical to the surface of the substrate. This is because it is necessary to transfer the line-and-space pattern onto the amorphous carbon film 3 with the size of the line-and-space pattern maintained. That is, first, the line-and-space pattern is completely transferred onto the amorphous carbon film 3, which is a lower hard mask material, by etching the amorphous carbon film 3 up to a midway depth of the upper portion thereof, and then completely etching the amorphous carbon film 3 using a new coating film as a mask. In such a process, the line-and-space pattern needs to be transferred with high accuracy.

As described above, the sidewall core is exposed by performing plural times of etching process during a double patterning process, and thus the film of the sidewall core is reduced. Therefore, it is necessary for the film to have a sufficient film thickness in consideration of the reduction in the film when the film is formed. Specifically, the film thickness of about 200 nm is necessary. If the sidewall core is formed so as to have such a film thickness by using a silicon-based material film, there is a concern that film peeling occurs in the interface between the amorphous carbon film 3 and the silicon oxynitride film 4 and the interface between the amorphous carbon film 3 and the wiring layer 2. This is because the silicon oxynitride film 4 has large stress due to weak adhesion between the amorphous carbon film 3 and the silicon-based material film. When the silicon-based material film is formed so as to have a relatively thin thickness and preferably have a thickness equal to or less than about 100 nm, it is possible prevent the problem with the film peeling. In this case, however, the film thickness is not sufficient during the double patterning process.

Due to this reason, the organic film is used as the material film of the sidewall core in this embodiment. Since the organic film formed by the spin coating method largely has no stress, this configuration works well with respect to the adhesion between the amorphous carbon film 3 and the silicon oxynitride film 4.

Since the heat-resistant temperature of the organic film formed by the spin coating method is low, it is necessary for the sacrificial film of the sidewall spacer or the embedded mask pattern formed on the organic film to have a temperature lower than the heat-resistant temperature. For this reason, the same organic film as that of the sidewall core is used in the embedded mask pattern. As the material of the sacrificial film, there is used a silicon oxide film which has etching selectivity with respect to the organic film and excellent step coverage. The sacrificial film is formed at a temperature equal to or less than 200° C. by the ALD method. Since the thickness of the silicon oxide film is, for example, about 25 nm, like the thin thickness of the film forming the minute opening, large stress rarely occurs and the amorphous carbon film can be prevented from being peeled off.

The pattern formed in the silicon oxynitride film 4 serving as the upper hard mask is a loop pattern in which both ends of two line patterns extending in the Y direction are connected to each other. Finally, it is necessary to form the independent wirings separated from each other, and thus it is necessary to separate both ends of the loop pattern in the Y direction from the line pattern. Moreover, the loop pattern of the silicon oxynitride film 4 is formed by the double patterning method, but it is difficult to form the pattern of the peripheral circuit with less regularity by the double patterning method. The following process is a process of demarcating the ends of the line pattern in the Y direction by removing the ends of the loop pattern in the Y direction by etching and adding a peripheral wiring pattern to the upper hard mask.

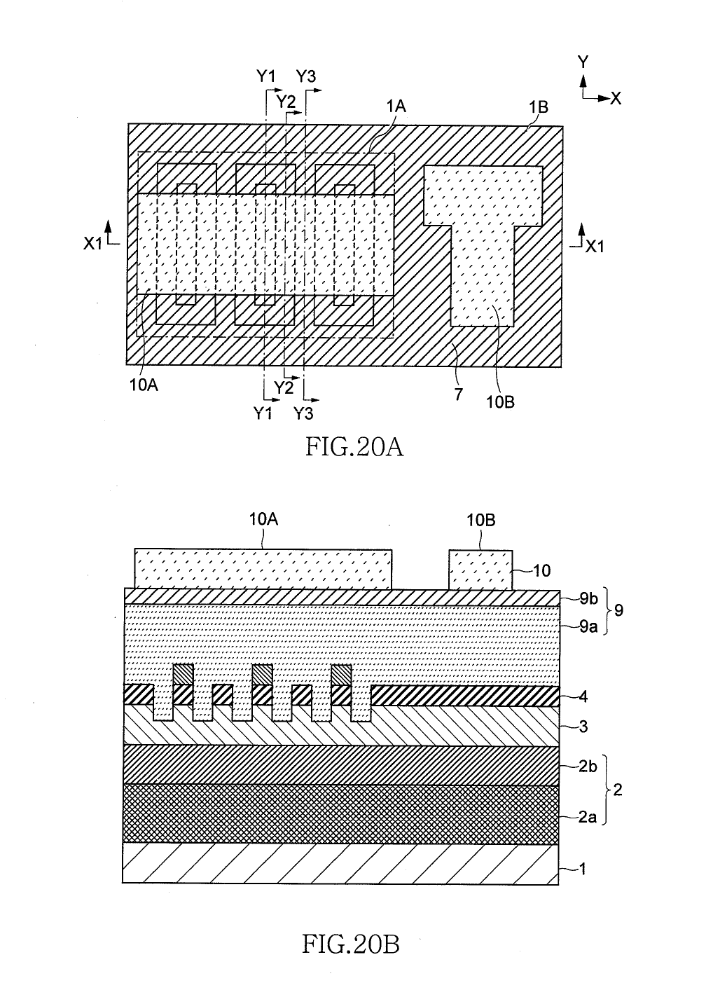

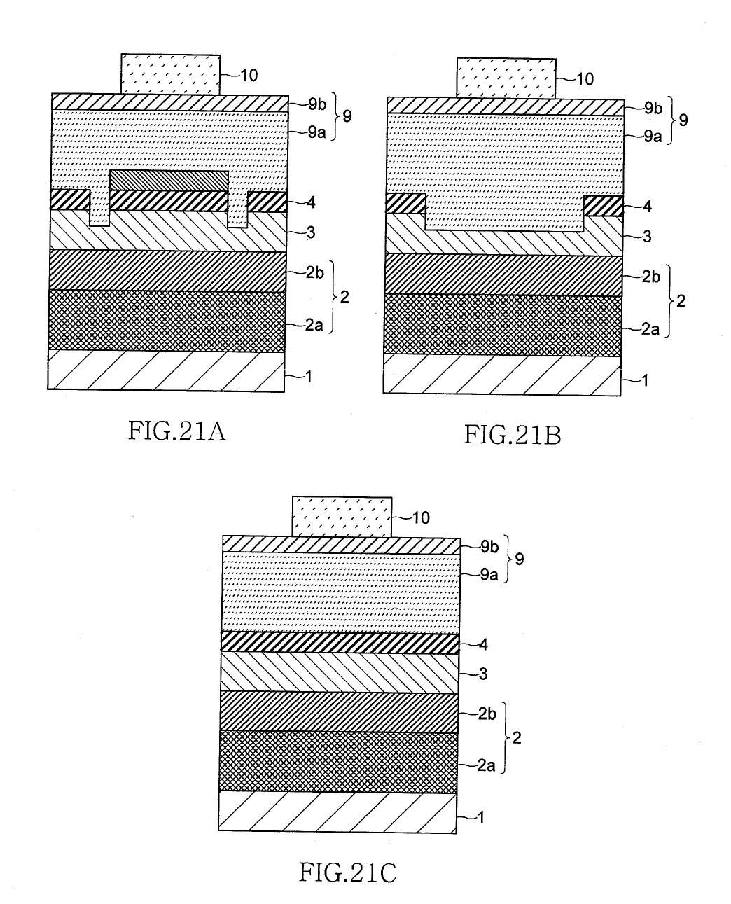

Next, as shown in FIGS. 20A and 20B and FIGS. 21A to 21C, a two-layered coating film 9 is formed on the entire surface of the silicon substrate 1 including the patterned silicon oxynitride film 4. The coating film includes an organic anti-reflection film 9a and a silicon-containing organic film 9b. The organic anti-reflection film 9a has a thickness of 200 nm and the silicon-containing organic film 9b has a thickness of 30 nm. The organic anti-reflection film 9a and the silicon-containing organic film 9b can be formed together within a temperature range from the normal temperature to 200° C. by a spin coating method.

Thereafter, a resist pattern 10 is formed to pattern the coating film 9. For example, the resist pattern 10 is formed by forming an ArF photoresist film by a spin coating method and then patterning the photoresist film using an ArF liquid immersion exposure apparatus. It is necessary to form the photoresist film at a temperature lower than the heat-resist temperature of the organic anti-reflection film 9a and the silicon-containing organic film 9b.

The resist pattern 10 according to this embodiment includes an array protection pattern 10A covering a line-and-space portion of a loop pattern in the memory cell array region (first region) 1A and a peripheral wiring pattern 10B covering the wiring-formed region in the peripheral circuit region (second region) 1B. The line-and-space portion of the loop pattern is covered with the array protection pattern 10A and both ends of the loop pattern are not covered therewith.

Here, the line-and-space portion of the loop pattern in the memory cell array region 1A is a processed region and the other portion (including both ends of the loop pattern) in the memory cell array region 1A is a non-processed region. That is, the non-processed region is not covered with the array protection pattern 10A and the processed region inside the memory cell array region 1A is all covered with the array protection patter 10A. A line-shaped sidewall core extends from the processed region to the non-processed region in the Y direction, and the plural line-shaped sidewall cores are arranged in parallel with each other in the X direction perpendicular to the Y direction.

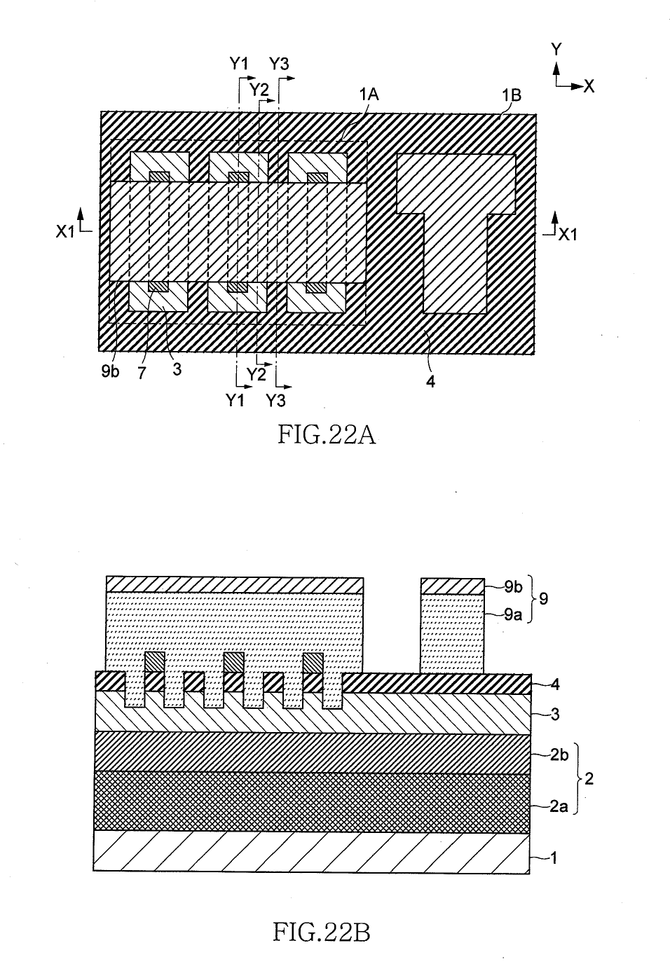

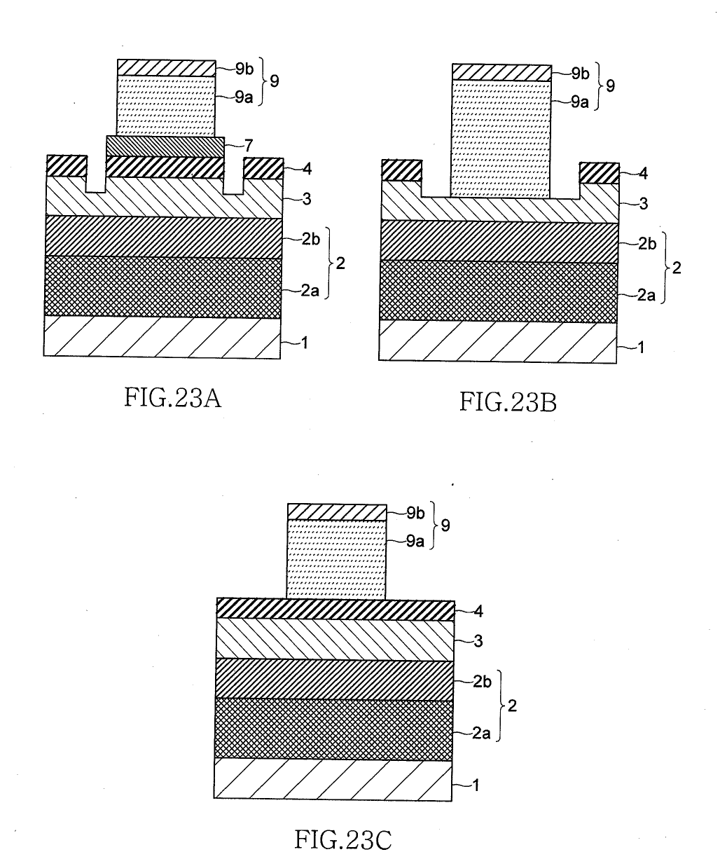

Next, as shown in FIGS. 22A and 22B and FIGS. 23A to 23C, the resist pattern 10 is transferred onto the coating film 9 by subjecting the coating film 9 to anisotropic etching using the resist pattern 10 as a mask. This etching is performed under the condition that etching selectivity is obtained with respect to the silicon oxynitride film 4 and the silicon oxide film 7. The silicon-containing organic film 5b and the organic anti-reflection film 5a are removed using an etching gas including oxygen (O₂) and carbon monoxide (CO), and then removing residues using an etching gas including hydrogen (H₂) and nitrogen (N₂). Thus, the organic anti-reflection film 9a and the silicon-containing organic film 9b of the coating film 9 are etched together to expose the silicon oxynitride film 4 of the underlying layer.

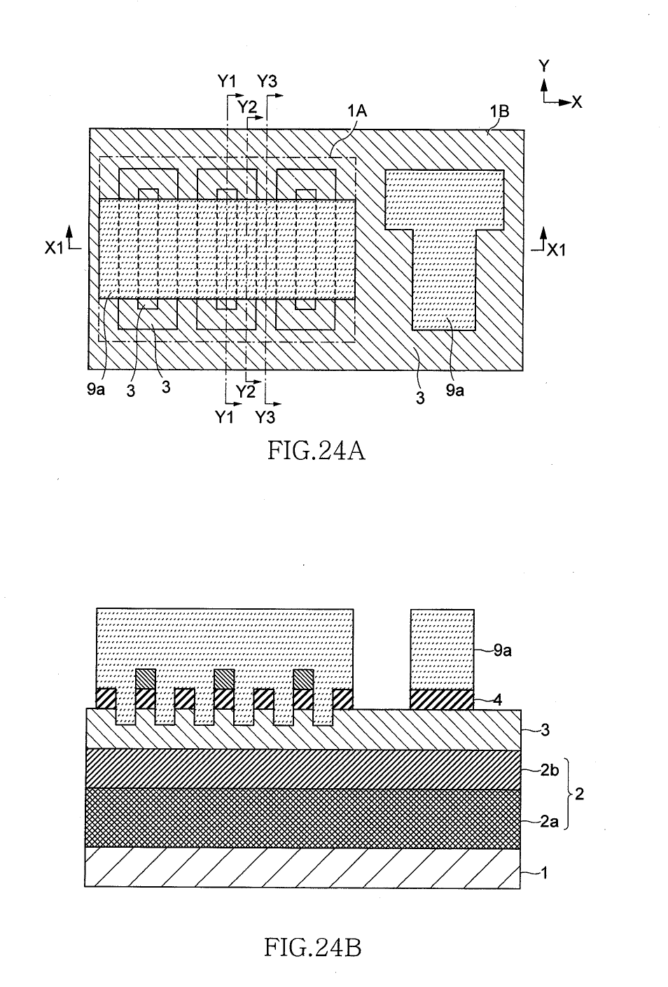

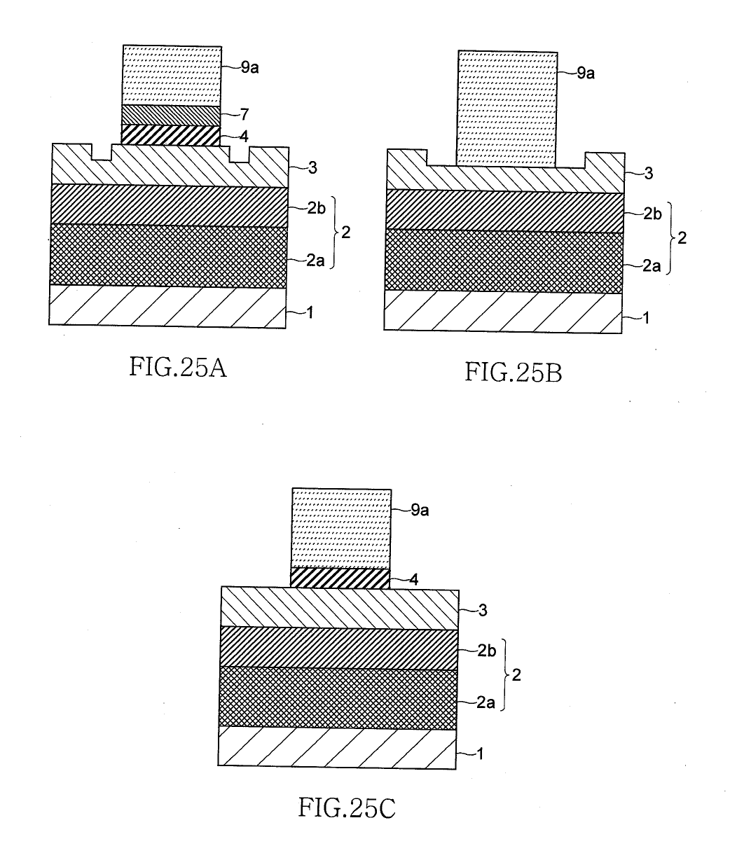

Next, as shown in FIGS. 24A and 24B and FIGS. 25A to 25C, the silicon oxynitride film 4 and the silicon oxide film 7 are removed by performing anisotropic etching using the coating film 9 as a mask. The etching is performed using an etching gas including carbon tetrafluoride (CF₄), carbon monoxide (CO), and argon (Ar) under the condition that etching selectivity is obtained with respect to the organic anti-reflection film 9a and the amorphous carbon film 3. Since the silicon-containing organic film 9b forming the surface of the mask is removed in the etching, the array protection pattern 10A and the peripheral wiring pattern 10B are covered with the organic anti-reflection film 9a and the amorphous carbon film 3 is exposed in the other regions.

In the etching, the silicon oxynitride film 4 is removed in the periphery of both ends of the loop pattern in the Y direction. Thereby, first and second line masks of the silicon oxynitride film 4, which are located on the left and right sides of the line pattern of the silicon oxide film 7, respectively, are separated from one another. Thus, in the array protection region covered with the organic anti-reflection film 9a, a line-and-space pattern in which a line pattern of the silicon oxide film 7 extending in the Y direction and a line pattern of the silicon oxynitride film 4 extending in the Y direction are alternately arranged is formed. A peripheral wiring pattern is formed in the silicon oxynitride film 4 in the peripheral wiring region. The patterns synthesized on the silicon oxynitride film 4 serve as an origin pattern of the lastly formed wiring pattern.

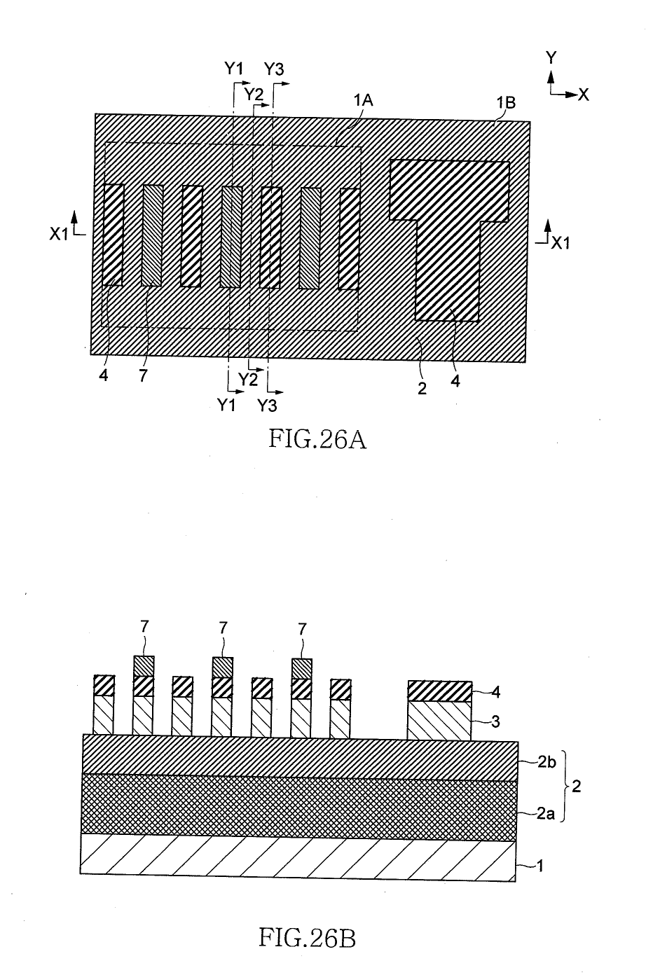

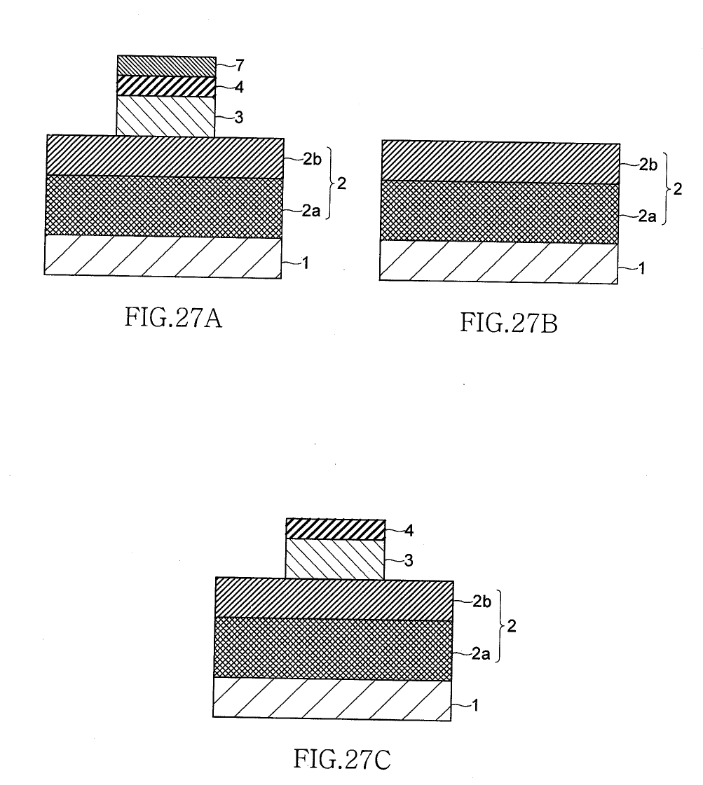

Next, as shown in FIGS. 26A and 26B and FIGS. 27A to 27C, the amorphous carbon film 3 is removed by performing anisotropic etching using the silicon oxide film 7 and the silicon oxynitride film 4 as masks. At this time, the organic anti-reflection film 9a is also removed together with the amorphous carbon film 3. This etching is performed under the condition that etching selectivity is obtained with respect to the silicon oxide film 7 and the silicon oxynitride film 4. This etching can be performed by removing the organic anti-reflection film 9a and the amorphous carbon film 3 using an etching gas which includes oxygen (O₂) and carbon monoxide (CO), and then removing residues using an etching gas which includes hydrogen (H₂) and nitrogen (N₂).

In this etching, the pattern of the silicon oxynitride 4 serving as the upper hard mask is transferred onto the amorphous carbon film 3. Thus, the line-and-space pattern processed with the size less than the photolithography resolution limit by using the sidewall spacer and the pattern with an arbitrary size exemplified as the alignment monitor mark are transferred onto the amorphous carbon film 3, and thus a common hard mask is completed in the memory cell array region 1A and the peripheral circuit region 1B.

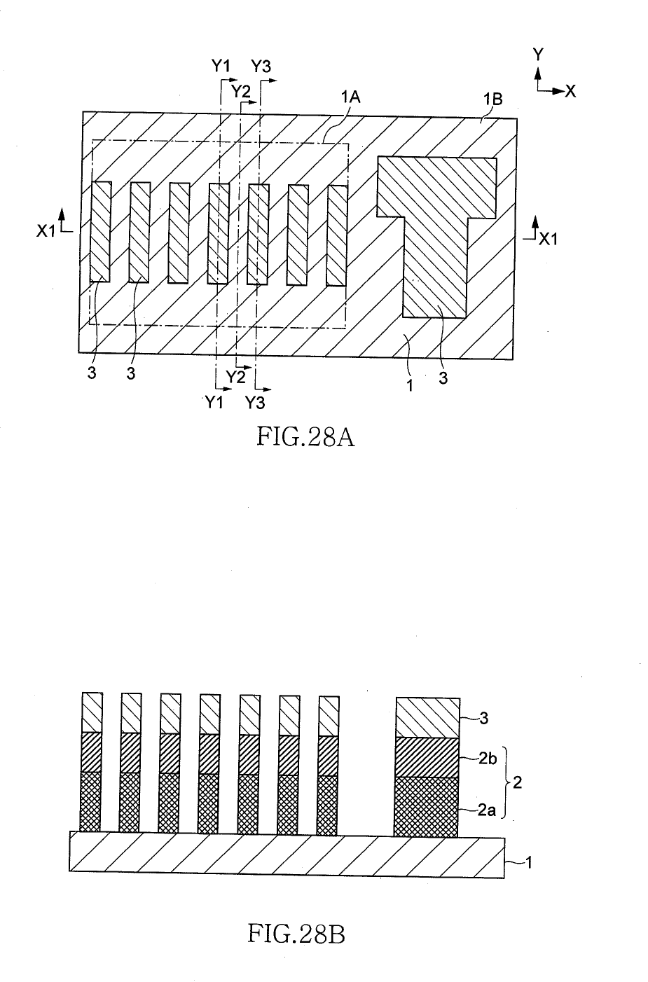

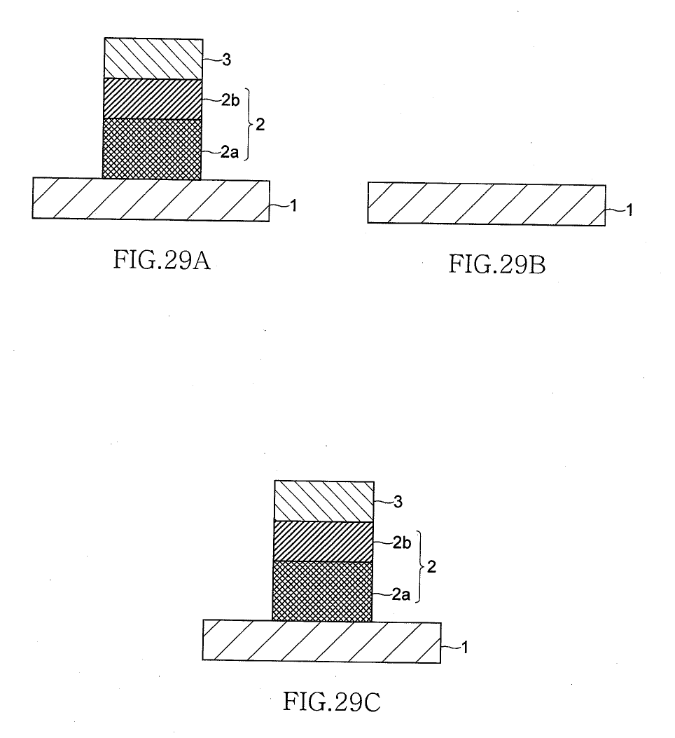

Next, as shown in FIGS. 28A and 28B and FIGS. 29A to 29C, the silicon nitride film 2b is subjected to anisotropic etching using the amorphous carbon film 3 as a mask and the pattern is transferred onto the silicon nitride film 2b. The etching is performed using an etching gas which includes carbon tetrafluoride (CF₄), carbon monoxide (CO), and argon (Ar) under the condition that etching selectivity is obtained with respect to the silicon nitride film 2b. By this etching, the surface of the tungsten film 2a is exposed and the silicon oxide film 7 and the silicon oxynitride film 4 formed on the amorphous carbon film 3 are removed. Subsequently, the tungsten film 2a is subjected to anisotropic etching using the silicon nitride film 2b as a mask, and thus the pattern is transferred onto the tungsten film 2a. This etching is performed under the condition that etching selectivity is obtained with respect to the surface of the underlying silicon substrate 1.

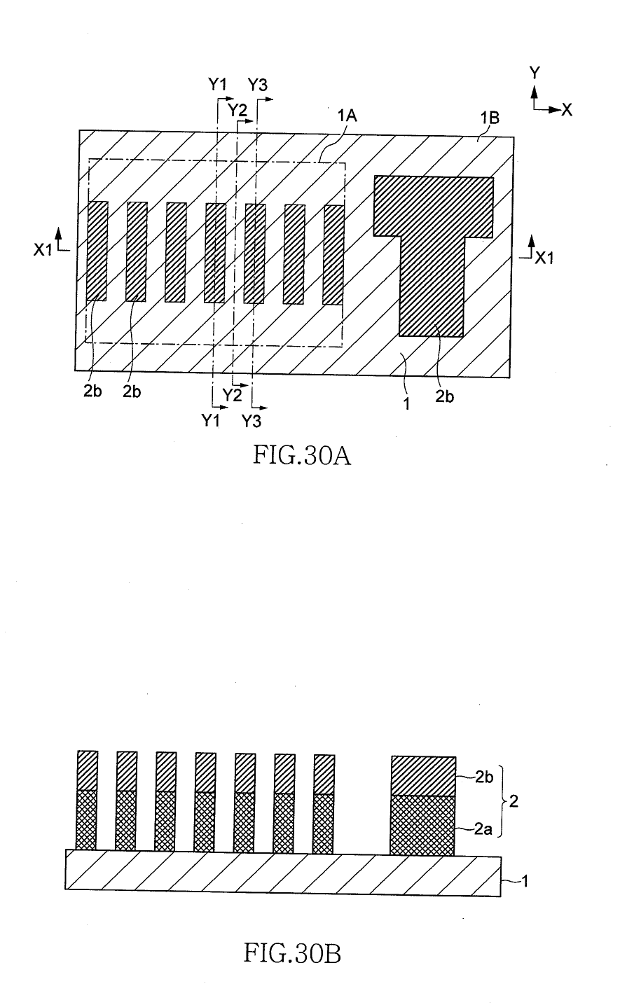

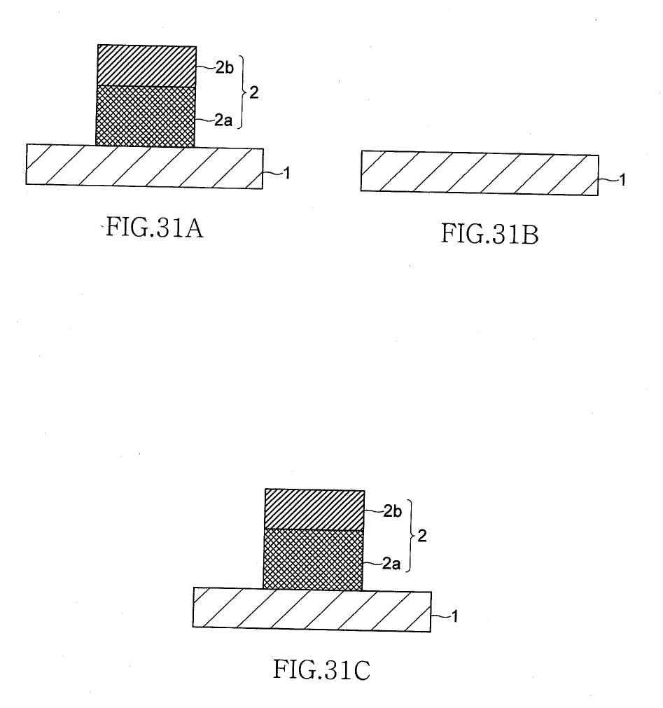

Finally, as shown in FIGS. 30A and 30B and FIGS. 31A to 31C, the amorphous carbon film 3 is removed by plasma ashing using an oxygen gas. Since the size of the wiring is rarely changed by the ashing, the length of the initially formed wring is ensured in the line-and-space pattern. Since the lower hard mask having the pattern formed by the double patterning method is formed from the amorphous carbon film 3, the lower hard mask can easily be removed by the ashing without damage to the wiring material or the substrate. Moreover, it is possible to obtain the advantage of removing the hard mask at low cost since the cost of the asking is low. As described above, the line-and-space pattern with double density of the minimum processing size is formed in the memory cell array region 1A and the peripheral wiring pattern such as the alignment monitor mark is formed in the peripheral circuit region 1B.

In this embodiment, as described above, the pattern with the size less than the photolithography resolution limit can be obtained by forming the coating film 5 (first coating film) including the organic anti-reflection film 5a and the silicon-containing organic film 5b on the member to be etched, which includes the amorphous carbon film 3 and the silicon oxynitride film 4, by the spin coating method; forming the sidewall core by patterning the coating film 5; forming the silicon oxide film 7 (first layer) covering at least the side surface of the sidewall core; forming the organic anti-reflection film 8 (second coating film) on the silicon oxide film 7 by the spin coating method; forming the embedded mask covering the concave portions 7a of the silicon oxide film 7 by etching the organic anti-reflection film 8; exposing a portion of the member to be etched which does not overlap the sidewall core or the embedded mask by etching the silicon oxide film 7; and then etching the member to be etched.

In this embodiment, the coating film 9 (third coating film) including the organic anti-reflection film 9a and the second silicon-containing organic film 9b is formed on the member to be etched by the spin coating method; the first and second patterns are respectively formed inside the memory cell array region 1A (first region), where the sidewall core is formed, and the peripheral circuit region 1B (second region), where the sidewall core is not formed, by patterning the coating film 9; the amorphous carbon film 3 is exposed by etching the silicon oxynitride film 4 using the first and second patterns as the masks; the first and second patterns are removed; and the amorphous carbon film 3 is etched using the silicon oxynitride film 4. Therefore, the pattern of the peripheral circuit region 1B can be formed when the patterning is performed to cut the loop pattern formed in the memory cell array region 1A. Thus, the pattern with the size less than the photolithography resolution limit and the pattern with an arbitrary size and an arbitrary shape can be simultaneously formed in the etching of the silicon oxide film 7. Accordingly, it is possible to simply synthesize both the patterns and very simply cut a part of the loop shape.

In this embodiment, the organic film (the organic anti-reflection film 5a) for the sidewall core is formed by the spin coating method after the wiring layer 2, the amorphous carbon film 3, and the silicon oxynitride film 4 are sequentially formed on the silicon substrate 1; and the embedded mask material embedded in the concave portions 7a of the silicon oxide film 7 is also the organic film (the organic anti-reflection film 8) and is formed by the spin coating method. Therefore, since no processing is performed at a high temperature exceeding 550° C., the coating film formed at the normal temperature is applicable. Thus, it is possible to prevent the peeling caused due to the stress occurring in the interface between the amorphous carbon film 3 and the silicon oxynitride film 4. Moreover, the ALD method is applied when the silicon oxide film 7 is formed to form the sidewall spacer. Therefore, since the silicon oxide film 7 can be formed at the normal temperature, the above-mentioned peeling can be prevented.

In this embodiment, the silicon oxide film 7 is formed on the organic anti-reflection film 5a of the sidewall core, and then the organic anti-reflection film 8 for the embedded mask is formed without performing the etch-back of the silicon oxide film 7. Therefore, the silicon oxide film 7 and the silicon oxynitride film 4 can be etched together by selecting the material of each film and the etching condition based on the fact that it is not necessary to expose the silicon oxynitride film serving as the upper hard mask. That is, the processing can be shortened by completing the processes at once from the etching of the silicon oxide film 7 to the transferring of the pattern onto the upper hard mask.

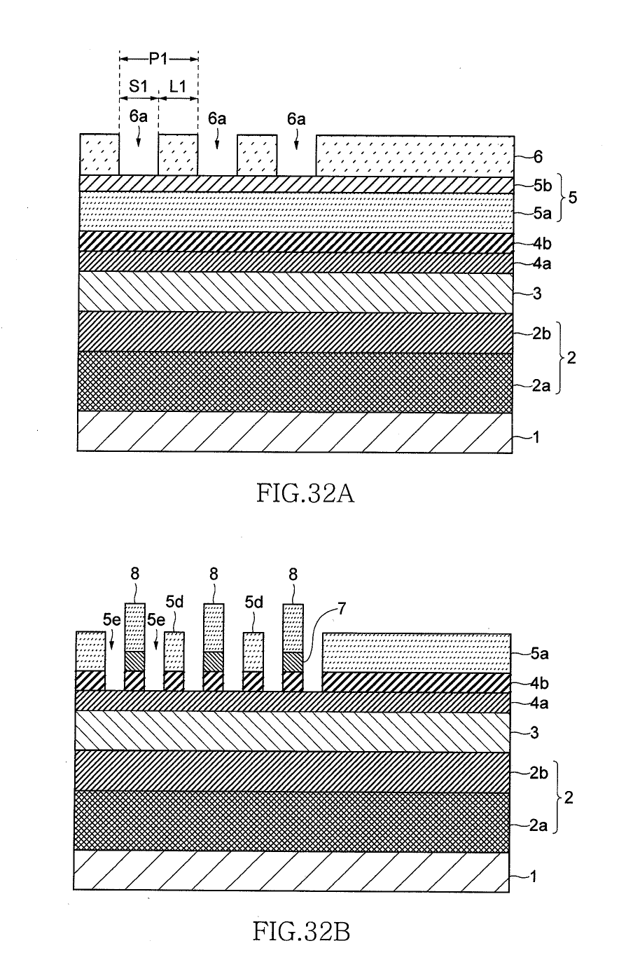

Next, a modified example of the first embodiment will be described in detail with reference to FIGS. 32A to 35B.

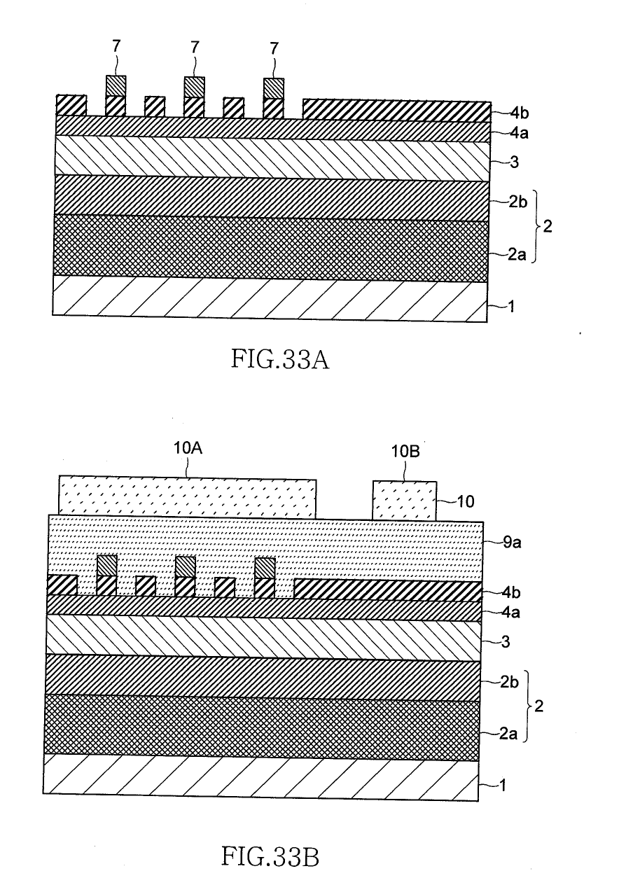

FIGS. 32A and 32B to FIGS. 35A and 35B are sectional views illustrating a process of manufacturing a semiconductor device according to a modified example of the first embodiment. FIGS. 32A and 32B correspond to FIGS. 6B and 16B of the first embodiment, respectively. FIG. 33A, 33B, 34A, 34B correspond to FIGS. 18B, 20B, 22B, 24B of the first embodiment, respectively.

In this modified example, as shown in FIG. 32A, the upper hard mask is not a single-layered film of the silicon oxynitride film 4, but is a two-layered film including a silicon nitride film 4a and a silicon oxide film 4b.

In the first embodiment, the silicon oxynitride film 4 serving as the upper hard mask is also patterned and the surface of the amorphous carbon film 3 is exposed in the etch-back (see FIGS. 16A and 16B) of the silicon oxide film 7 for the sidewall spacer. Therefore, the exposed surface of the amorphous carbon film 3 is etched in the subsequent process (see FIGS. 17A to 17C) of removing the organic anti-reflection film 5a.

In this modified example, as shown in FIG. 32B, only the silicon oxide film 4b is patterned among the upper hard masks and the silicon nitride film 4a is not patterned in the etch-back of the silicon oxide film 7 for the sidewall spacer. Therefore, the amorphous carbon film 3 is not exposed and the surface of the amorphous carbon film 3 is covered with the silicon nitride film 4a. Accordingly, the amorphous carbon film 3 is not etched and is protected in the process of removing the organic anti-reflection film 5a and the organic anti-reflection film 8 shown in FIG. 33A.

Next, the ends of the loop pattern in the Y direction are removed by etching to demarcate the ends of the line pattern in the Y direction. Moreover, to implement a process to add peripheral wiring pattern to the upper hard masks, as shown in FIG. 33B, the organic anti-reflection film 9a and the resist pattern 10 formed of a photoresist film are formed on the entire surface of the silicon substrate 1 including the patterned silicon oxide film 4b. Unlike the first embodiment, in this modified example, the silicon-containing organic film 9b is not formed on the surface of the organic anti-reflection film 9a, but the amorphous carbon film 3 is covered with the silicon nitride film 4a. Therefore, even when the resist pattern 10 is formed again, it is possible to prevent the unintentional etching of the amorphous carbon film 3. Accordingly, since the process of forming the coating film can be simplified, the manufacturing cost can be reduced.

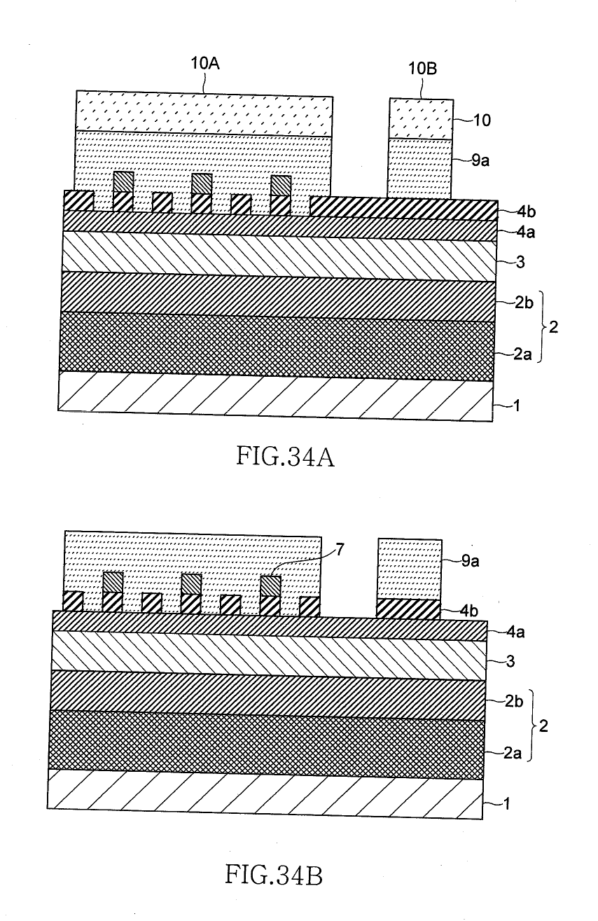

Next, as shown in FIG. 34A, the resist pattern 10 is transferred onto the organic anti-reflection film 9a by subjecting the organic anti-reflection film 9a to anisotropic etching using the resist pattern 10 as a mask. Thus, the organic anti-reflection film 9a of the coating film is etched to expose the silicon oxide film 4b of the underlying layer.

Next, as shown in FIG. 34B, the silicon oxide film 4b is removed by performing anisotropic etching using the organic anti-reflection film 9a as a mask. In this etching, the silicon oxide film 4b is removed in the periphery of both ends of the loop pattern in the Y direction, and the first and second line masks are separated from each other in the silicon oxide film 4b located on the left and right sides of the line pattern of the silicon oxide film 7. Thus, it is possible to form the line-and-space pattern in which the line pattern of the silicon oxide film 7 extending in the Y direction and the line pattern of the silicon oxide film 4b extending in the Y direction are alternately arranged in the array protection region covered with the organic anti-reflection film 9a. A peripheral wiring pattern is formed in the silicon oxynitride film 4b in the peripheral wiring region. The patterns synthesized on the silicon oxynitride film 4b serve as an origin pattern of the lastly formed wiring pattern.

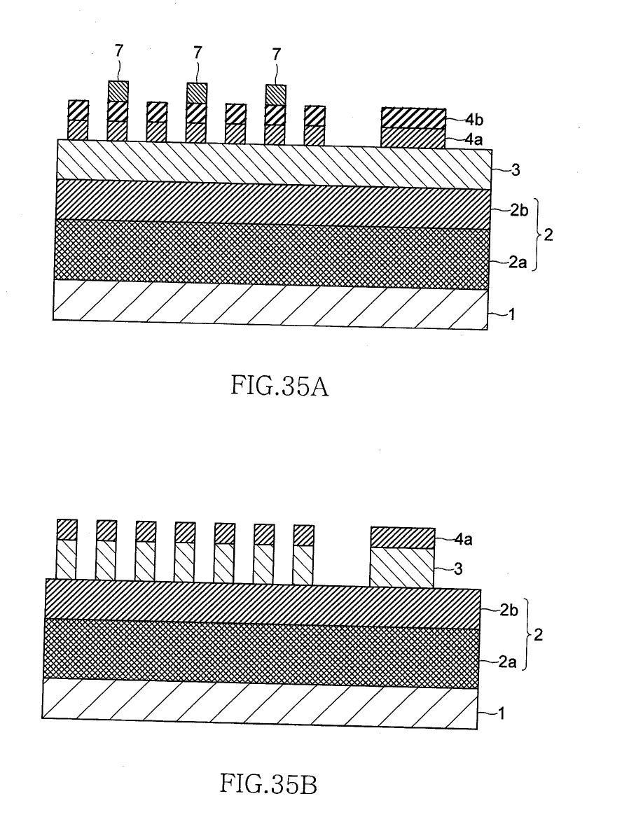

Next, as shown in FIG. 35A, the silicon nitride film 4a and the organic anti-reflection film 9a are removed by performing anisotropic etching using the silicon oxide film 4b as a mask. Moreover, as shown in FIG. 35B, the amorphous carbon film 3 is removed by performing anisotropic etching using the silicon oxide film 4b as a mask. Thereafter, the semiconductor device according to this modified example is completed through the same processes as those of the first embodiment, such as the anisotropic etching of the silicon nitride film 2b and the tungsten film 2a.

As indicated above, in the modified example, no unintentional concave portion is formed in the amorphous carbon film 3, since the upper hard mask is formed as the two-layered film including the silicon nitride film 4a and the silicon oxide film 4b. Therefore, the advantage can be obtained since the depths of the grooves in the memory cell array region 1A can be made to be shallow and coating is uniformly performed more easily on the surface of the semiconductor substrate in which the grooves are formed.

Next, a process of manufacturing a semiconductor device will be described in detail according to a second embodiment of the invention.

In the second embodiment, the organic anti-reflection film which is used as an embedded mask is used even when the peripheral wiring pattern is formed and when a partial cutting pattern of the loop pattern is formed. Since the processes from the process of forming the film in FIGS. 6A and 6B, to the process of forming the silicon oxide film 7 in FIGS. 8A and 8B are the same as those of the first embodiment, the detailed description thereof will not be repeated.

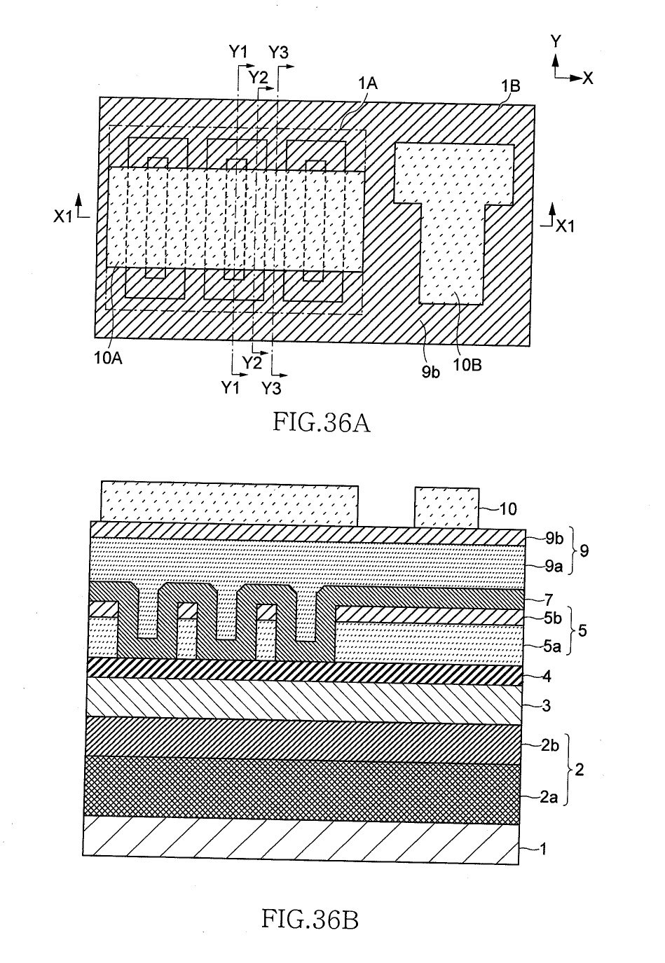

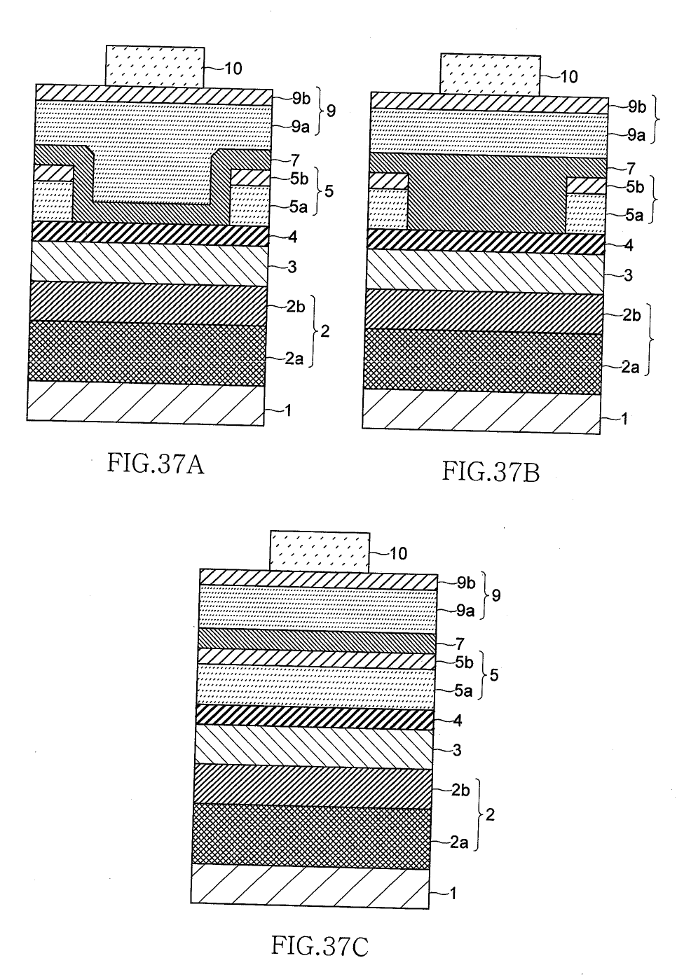

Next, as shown in FIGS. 36A and 36B and FIGS. 37A to 37C, the two-layered coating film 9 is formed on the entire surface of the substrate. The two-layered coating film 9 includes the organic anti-reflection film 9a and the silicon-containing organic film 9b. The thickness of the organic anti-reflection film 9b is 200 nm and the thickness of the silicon-containing organic film 9b is 30 nm. The organic anti-reflection film 9a and the silicon-containing organic film 9b can be formed by a spin coating method. The organic anti-reflection film 9a and the silicon-containing organic film 9b can be formed within a temperature range from the normal temperature to 200° C. However, it is necessary to form the organic anti-reflection film 9a and the silicon-containing organic film 9b at a temperature lower than the heat-resistant temperature of the organic anti-reflection film 5a and the silicon-containing organic film 5b.

Thereafter, the resist pattern 10 is formed to pattern the coating film 9. For example, the resist pattern 10 is formed by forming the ArF photoresist film by a spin coating method and then patterning the photoresist film using an ArF liquid immersion exposure apparatus. The photoresist film can be formed within the temperature range from the normal temperature to about 200° C., as in the coating film 5. However, it is necessary to form the photoresist film at a temperature lower than the heat-resist temperature of the organic anti-reflection film 9a and the silicon-containing organic film 9b.

The resist pattern according to this embodiment includes the array protection pattern 10A covering the line-and-space portion of the loop pattern in the memory cell array region (first region) 1A and the peripheral wiring pattern 10B covering the wiring-formed region in the peripheral circuit region (second region) 1B. The line-and-pace portion of the loop pattern is covered with the array protection pattern 10A and both ends of the loop pattern in the Y direction are not covered therewith.

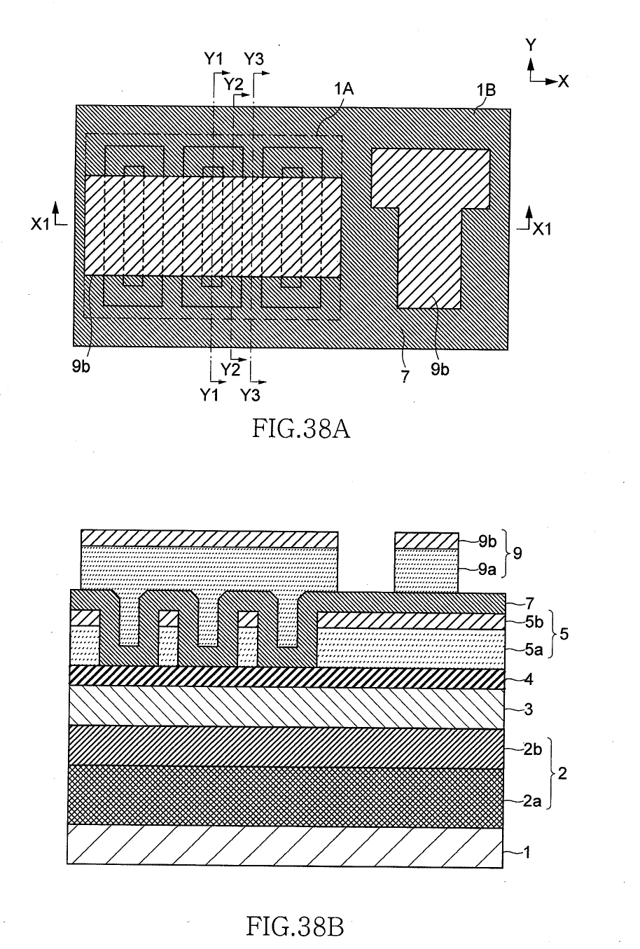

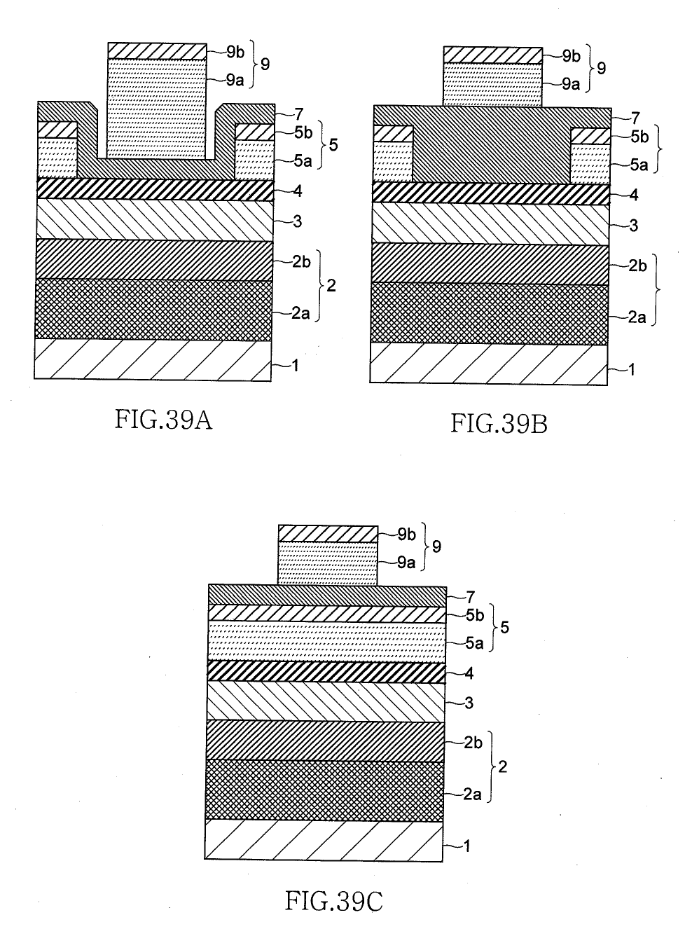

Next, as shown in FIGS. 38A and 38B and FIGS. 39A to 39C, the resist pattern 10 is transferred onto the coating film 9 by subjecting the coating film 9 to anisotropic etching using the resist pattern 10 as a mask. This etching is performed under the condition that etching selectivity is obtained with respect to the silicon oxide film 7. The silicon-containing organic film 5b and the organic anti-reflection film 5a are removed using an etching gas including oxygen (O₂) and carbon monoxide (CO), and then removing residues using an etching gas which includes hydrogen (H₂) and nitrogen (N₂). Thus, the organic anti-reflection film 9a and the silicon-containing organic film 9b of the coating film 9 are etched together to expose the silicon oxide film 7 of the underlying layer.

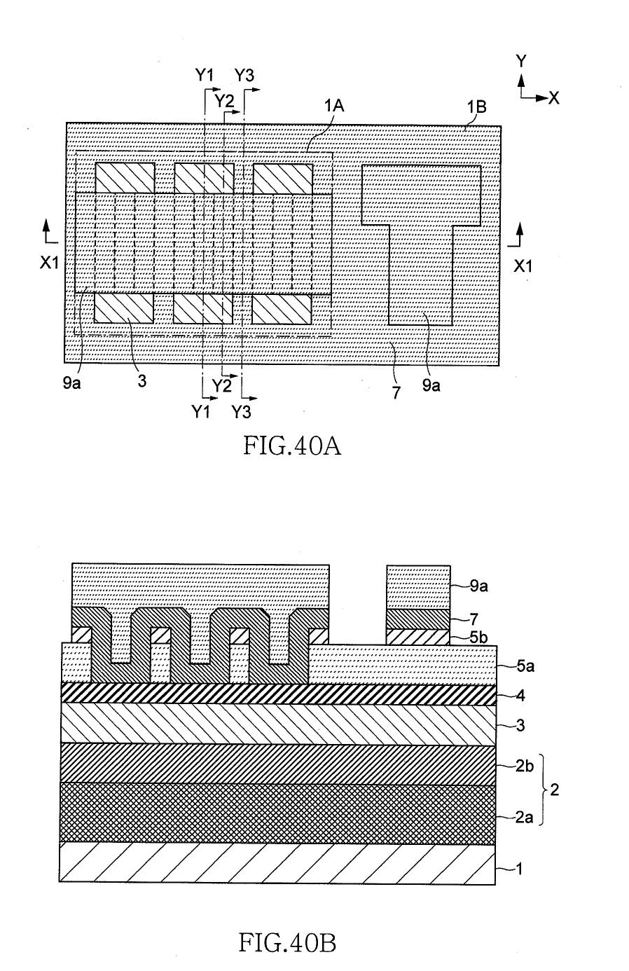

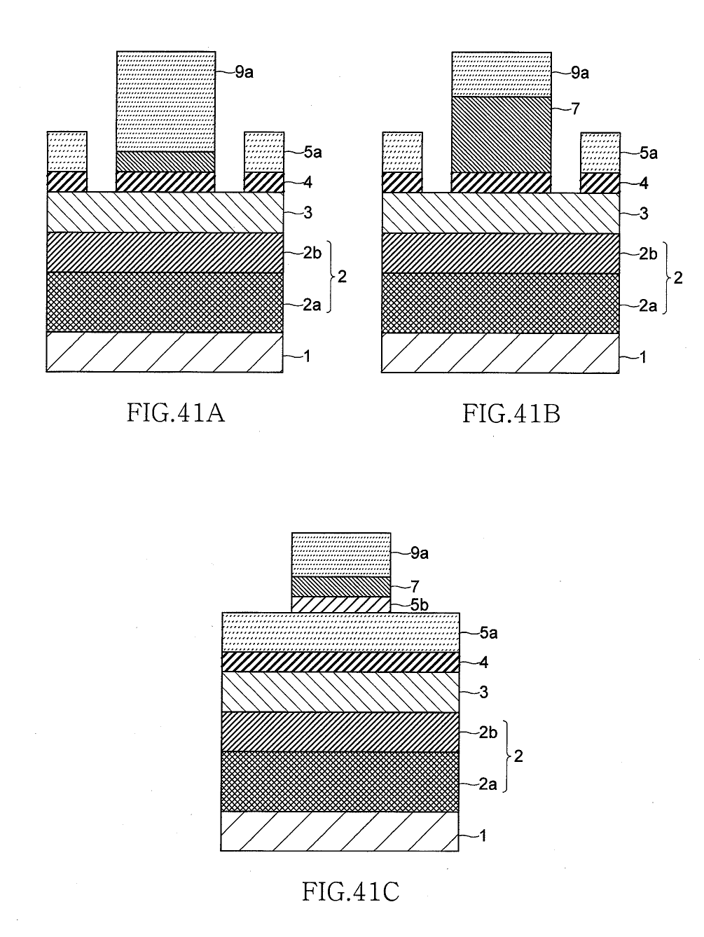

Next, as shown in FIGS. 40A and 40B and FIGS. 41A to 41C, the silicon oxide film 7 is removed by performing anisotropic etching using the coating film 9 as a mask. This etching is performed under the condition that etching selectivity is obtained with respect to the organic anti-reflection film 9a and the amorphous carbon film 3. The gas including carbon tetrafluoride (CF₄), carbon monoxide (CO), and argon (Ar) can be used as the etching gas. Since the silicon-containing organic film 9b of the surface layer of the mask is removed and the second silicon-containing organic film 5b are removed by this etching, the array protection pattern 10A and the peripheral wiring pattern 10B are covered with the organic anti-reflection film 9a and the organic anti-reflection film 5a is exposed in the other region. As shown in FIGS. 41A and 41B, the silicon oxynitride film 4 directly below the silicon oxide film 7 is removed and thus a part of the amorphous carbon film 3 is exposed.

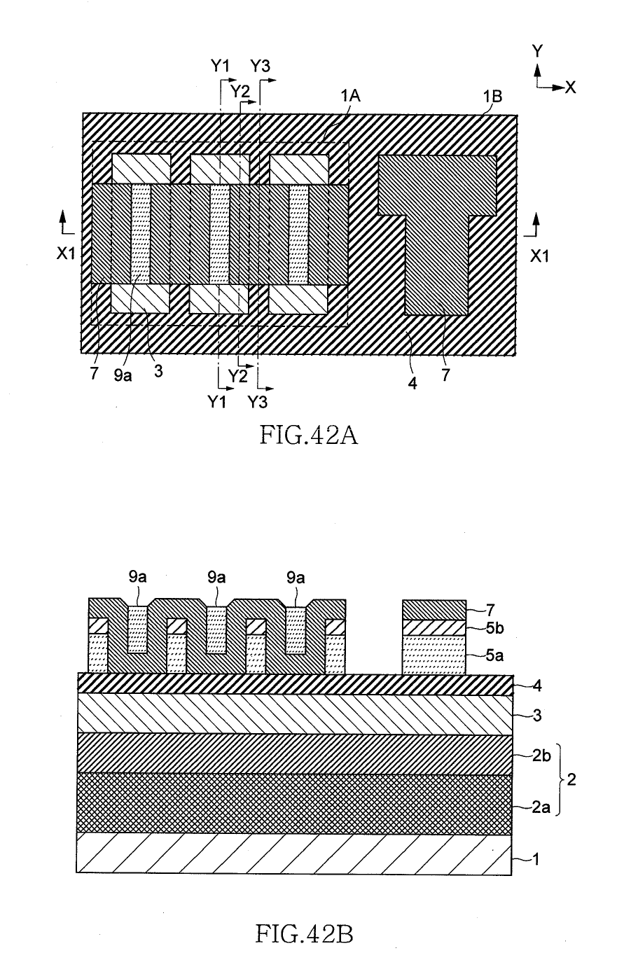

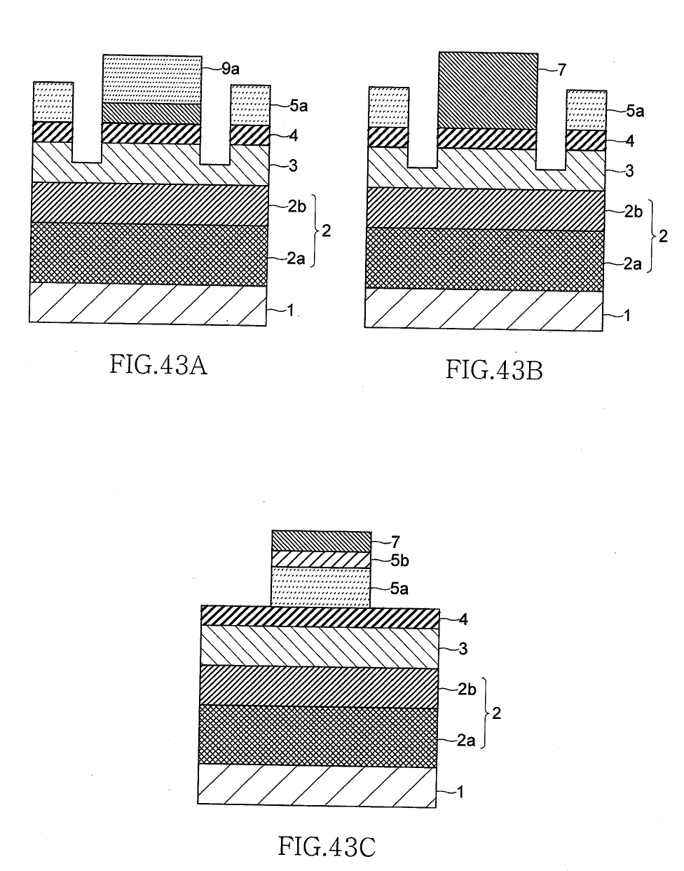

Next, as shown in FIGS. 42A and 42B and FIGS. 43A to 43C, the organic anti-reflection film 9a is made to remain only in the concave portions 7a of the silicon oxide film 7 by etching back the organic anti-reflection film 9a. The gas including oxygen (O₂) and carbon monoxide (CO) can be used as an etching gas. Since the organic anti-reflection film 8 is embedded across the entire width of each concave portion 7a in the width direction (X direction) of the concave portion 7a, the width of the embedded mask pattern of the organic anti-reflection film 8 is the same as the width of the concave portion 7a. As described above, when the flatness of the organic anti-reflection film 8 is good, the heights of the embedded mask patterns formed in the respective concave portions 7a are the same as each other, thereby forming a uniform pattern on the wafer surface.

In the etch-back, the organic anti-reflection film 5a is removed using the silicon oxide film 7 as a mask and the silicon oxynitride film 4 of the underlying layer is also exposed. As shown in FIGS. 43A and 43B, etched is a part of the amorphous carbon film 3 which is not covered with the silicon oxynitride film 4. Thus, concave portions are formed on the exposed surface of the amorphous carbon film 3.

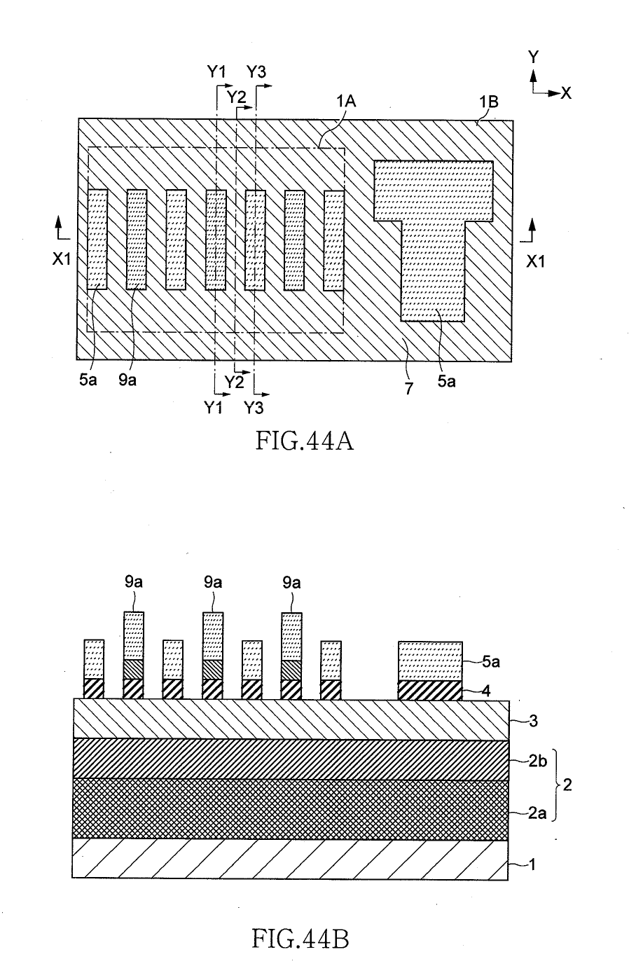

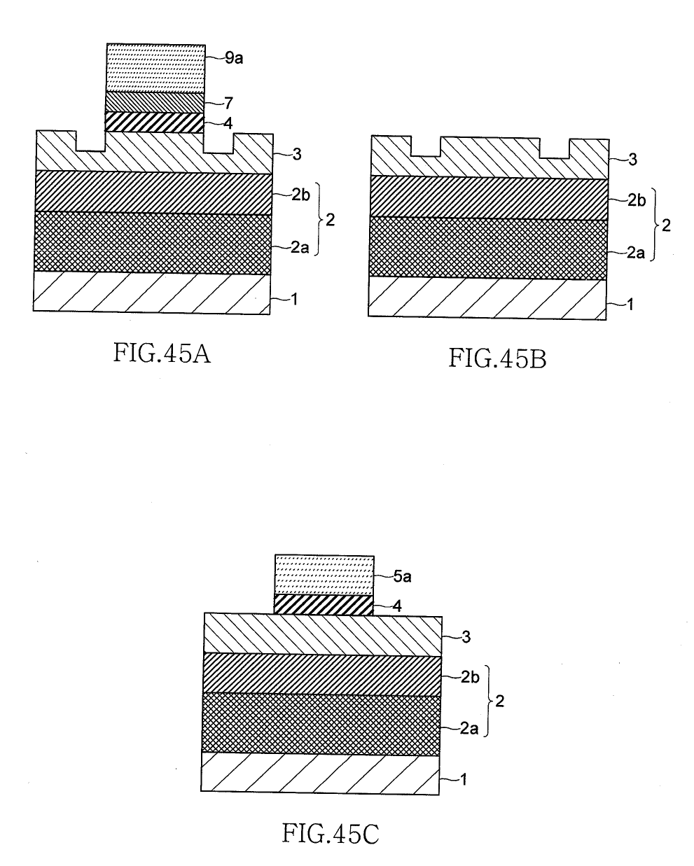

Next, as shown in FIGS. 44A and 44B and FIGS. 45A to 45C, the sidewall spacer of the silicon oxide film 7 exposed from each opening is removed by anisotropic etching. The etching is performed under the condition that etching selectivity is obtained with respect to the organic anti-reflection film 9a and the organic anti-reflection film 5a. A gas which includes carbon tetrafluoride (CF₄), carbon monoxide (CO), and argon (Ar) can be used as the etching gas. By this etching, the silicon-containing organic film 5b is removed and the silicon oxynitride film 4 directly below the sidewall spacers is also removed together with the silicon oxide film 7. Therefore, the surface of the amorphous carbon film 3 is further exposed. Since the organic anti-reflection film 9a is embedded in each concave portion 7a of the silicon oxide film 7, the silicon oxide film 7 and the silicon oxynitride film 4 directly below the organic anti-reflection film 9a are not removed and only the sidewall spacers and the exposed upper surface are removed. According to the patterning method, width precision can be improved compared to a case where the sidewall spacers are actually formed by etching back the silicon oxide film 7.

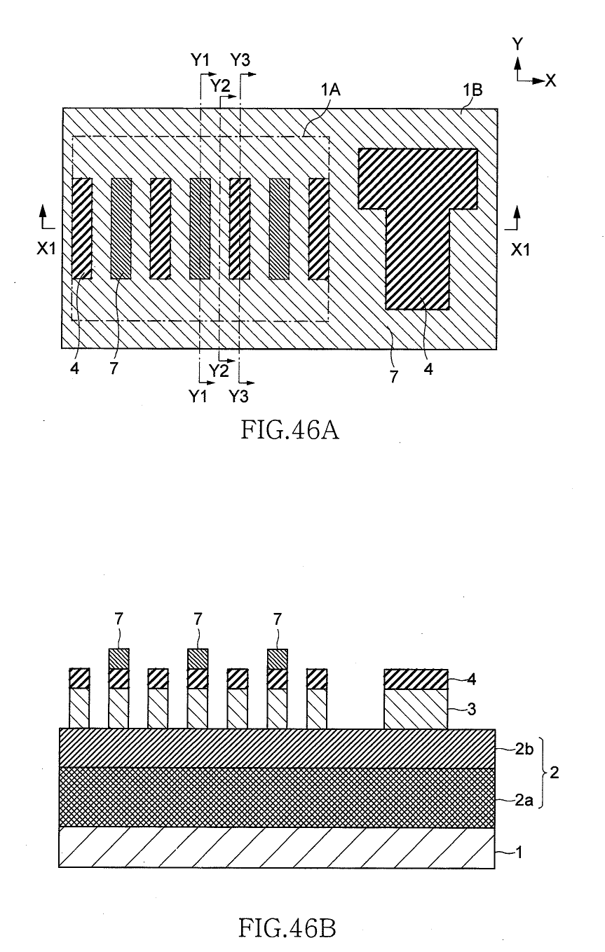

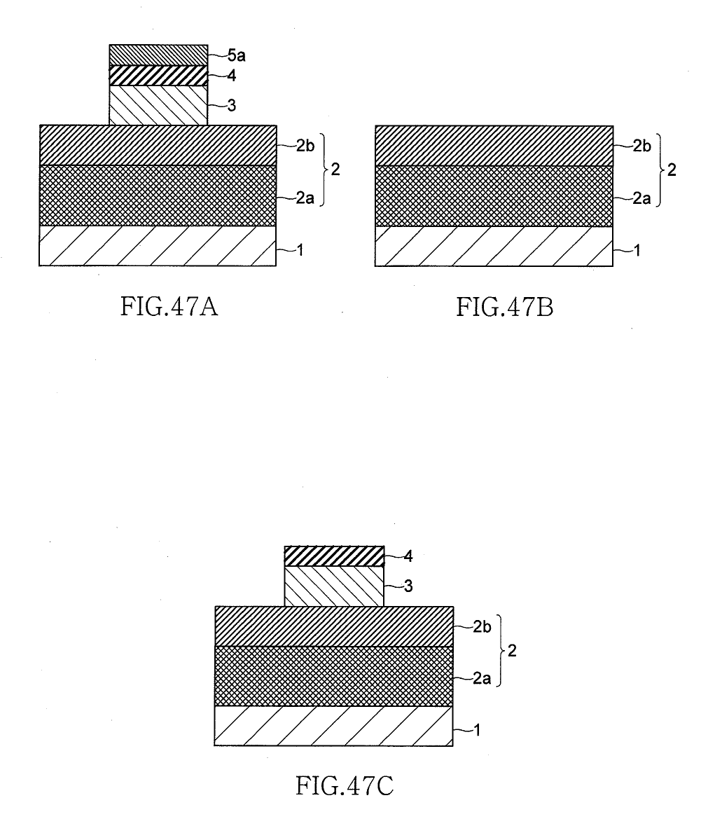

Next, as shown in FIGS. 46A and 46B and FIGS. 47A to 47C, the amorphous carbon film 3 is removed by performing anisotropic etching using the silicon oxide film 7 and the silicon oxynitride film 4 as masks. At this time, the organic anti-reflection film 9a is also removed together with the amorphous carbon film 3. This etching is performed under the condition that etching selectivity is obtained with respect to the silicon oxide film 7 and the silicon oxynitride film 4. This etching can be performed by removing the organic anti-reflection film 9a and the amorphous carbon film 3 using an etching gas which includes oxygen (O₂) and carbon monoxide (CO), and then removing residues using an etching gas which includes hydrogen (H₂) and nitrogen (N₂).

Next, as shown in FIGS. 28A and 28B and FIGS. 29A to 29C of the first embodiment, the silicon nitride film 2b is subjected to anisotropic etching using the amorphous carbon film 3 as a mask and the pattern is transferred onto the silicon nitride film 2b. The etching is performed using an etching gas which includes carbon tetrafluoride (CF₄), carbon monoxide (CO), and argon (Ar) under the condition that etching selectivity is obtained with respect to the tungsten film 2a. By this etching, the surface of the tungsten film 2a is exposed and the silicon oxide film 7 and the silicon oxynitride film 4 formed on the amorphous carbon film 3 are removed. Subsequently, the tungsten film 2a is subjected to anisotropic etching using the silicon nitride film 2b as a mask, and thus the pattern is transferred onto the tungsten film 2a. This etching is performed under the condition that etching selectivity is obtained with respect to the surface of the silicon substrate 1 of the underlying substrate.

Finally, as shown in FIGS. 30A and 30B and FIGS. 31A to 31C of the first embodiment, the amorphous carbon film 3 is removed using an oxygen gas by plasma ashing. Since the size of the wiring is rarely changed by the ashing, the length of the initially formed wring is ensured in the line-and-space pattern. Since the lower hard mask having the pattern formed by the double patterning method is formed from the amorphous carbon film 3, the amorphous carbon film 3 can easily be removed by the ashing without damage to the wiring material or the substrate. Moreover, it is possible to obtain the advantage of removing the hard mask at low cost since the cost of the ashing is low. As described above, the line-and-space pattern with double density of the minimum processing size is formed in the memory cell array region 1A and the peripheral wiring pattern such as the alignment monitor mark is formed in the peripheral circuit region 1B.

In this embodiment, as described above, the organic anti-reflection film 9a used as the embedded mask is also used when the peripheral pattern is formed and a partial cutting separating pattern of the loop shape is formed. Therefore, in addition to the operational advantage of the first embodiment, it is possible to shorten the manufacturing process and reduce the manufacturing cost. Since the embedded mask is formed after the formation of the peripheral pattern and the partial cutting separating pattern of the loop shape, removing of the organic anti-reflection film 5a of the sidewall core and the organic anti-reflection film 9a of the embedded mask and patterning of the amorphous carbon film 3 can be executed concurrently. Therefore, the manufacturing process can be further shortened.

Next, a process of manufacturing a semiconductor device will be described in detail according to a third embodiment of the invention.

The third embodiment is different from the first and second embodiments in that there is provided dummy spaces 5f at both X-directional ends of the memory cell array region 1A (at areas between an after-mentioned land 5g and line-and-space pattern consisting of the openings 5c and the sidewall cores 5d). As described in detail below, the dummy spaces 5f are provided to prevent the organic anti-reflection film 9a from growing thick on the line-and-space pattern, especially, at areas peripheral to the memory cell array region 1A. Because the finished pattern width tends to change if the thickness of the organic anti-reflection film 9a changes, the dummy spaces 5f can minimize the variety of the pattern width.

In this embodiment, a case of forming a trench pattern will be described instead of the bit line pattern described in the first and second embodiments. When the dummy spaces 5f are used, the silicon oxide film 7 is also formed on the outside side surfaces of the dummy spaces 5f (an inner side surface of the after-mentioned land 5g). When the trench pattern is etched, as in the silicon oxide film 7 formed on the side surface of the sidewall core 5d, a trench may also be formed at the position corresponding to the silicon oxide film 7 formed on the side surface of the land 5g. In order to prevent the formation of the trench, in this embodiment, formed is a mask pattern (a resist pattern 11 described below) which covers the region overlapping the silicon oxide film 7 formed on the side surface of the land 5g in relation to a vertical direction, and then the organic anti-reflection film 9a is etched back. Hereinafter, the differences between this embodiment and the first and second embodiments will mainly be described in detail.

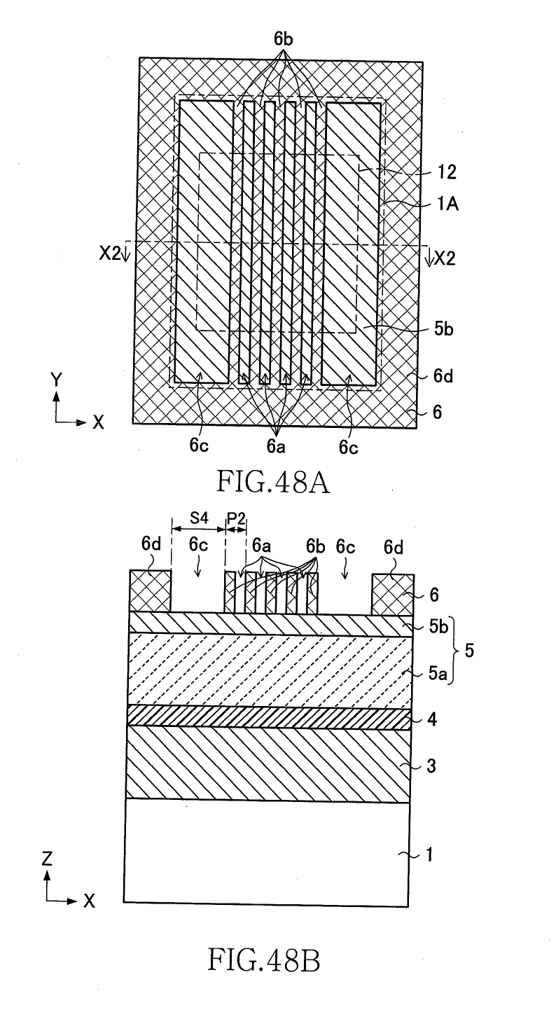

FIGS. 48A to 54A and 48B to 54B are plan views illustrating a method of manufacturing a semiconductor device according to this embodiment and sectional views taken along the lines X2-X2, respectively. In the drawings, a region corresponding to the above-described memory cell array region 1A is shown and the land 5g surrounding the memory cell array region 1A is shown. The peripheral circuit region 1B is not shown.

In the process of manufacturing the semiconductor device according to this embodiment, as shown in FIGS. 48A and 48B, the amorphous carbon film 3, the silicon oxynitride film 4, and the coating film 5 (including the organic anti-reflection film 5a and the silicon-containing organic film 5b) are first sequentially formed on the silicon substrate 1. The silicon substrate 1 according to this embodiment may be a non-processed silicon substrate or a substrate including functional layers such as an impurity diffusion layer, an insulation film, and a metal film. This embodiment is different from the first and second embodiments in that no wiring layer 2 is formed. The reason for forming no wiring layer 2 is to form a trench pattern instead of the line-and-space pattern. Since the specific configurations (the forming material, thickness, and film forming condition) of respective films are the same those of the first embodiment, the detailed description will not be repeated.

The coating film 5 is formed, and then the resist pattern 6 is formed to pattern the coating film 5, as shown in FIGS. 48A and 48B. The forming material, thickness, film forming condition, and the like of the resist pattern 6 are the same as those described in the first embodiment.

The resist pattern 6 according to this embodiment includes a land pattern 6d surrounding the memory cell array region 1A in addition to the same line-and-space pattern (the openings 6a and the resist line patterns 6b) as that of the first embodiment inside the processed region (which is a region where a trench pattern is formed) 12 of the memory cell array region 1A. The land pattern 6d is formed along the outer circumference of the memory cell array region 1A. The openings 6a and the resist line patterns 6b extend in the Y direction and are alternately arranged at a pitch P2=100 nm in the X direction. The openings 6a and the resist line patterns 6b are formed out of a processed region 12 and both ends of each resist line pattern 6b in the Y direction are connected to the land pattern 6d. Dummy spaces 6c with S4=500 nm are formed between the land patterns 6d and two resist line patterns 6b located at both ends of the line-and-space pattern in the X direction.

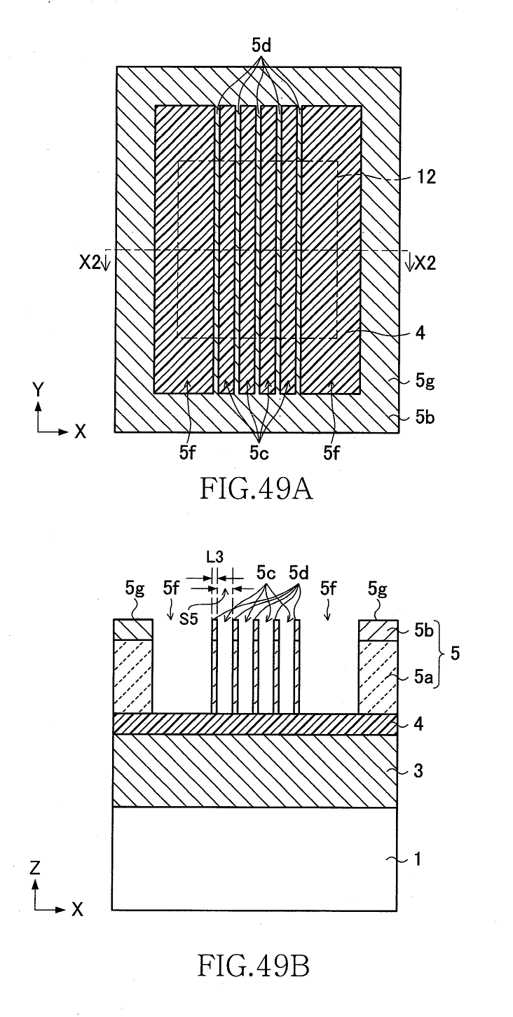

Next, as shown in FIGS. 49A and 49B, the resist pattern 6 is transferred onto the coating film 5 by subjecting the coating film 5 to anisotropic etching using the resist pattern 6 as a mask. The etching condition and the like are the same as those of the first embodiment. Moreover, the sliming process is performed, as in the first embodiment. As a consequence, the line-and-space with a line with L3=25 nm and a space width S5=75 nm is transferred onto the coating film 5 and the openings 5c and the sidewall cores 5d are formed. Moreover, the dummy spaces 5f and the land 5g are formed at the position corresponding to the dummy spaces 6c and the land pattern 6d, respectively. The X-directional width of each of the dummy spaces 5f is wider than the X-directional width of each of the openings 5c.

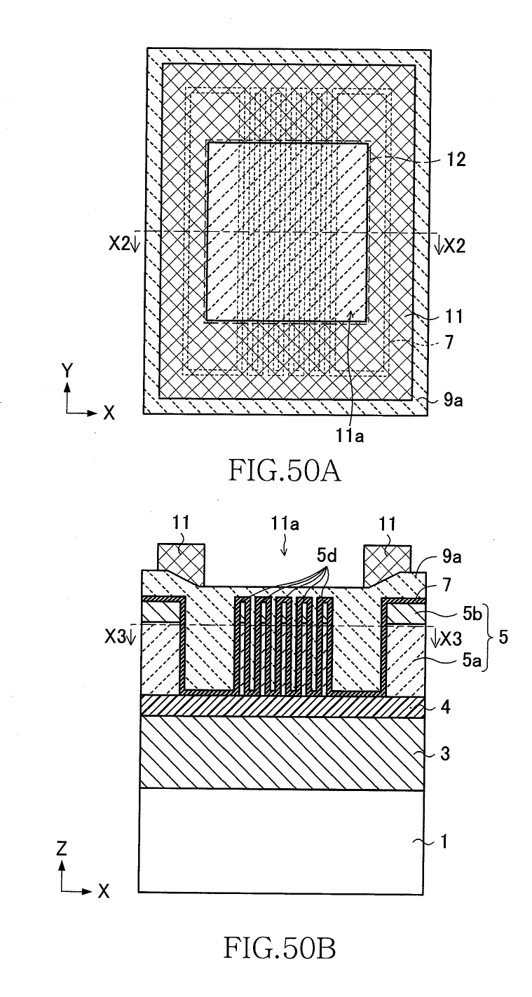

Next, as shown in FIGS. 50A and 50B, the silicon oxide film 7 is formed to cover the exposed surface. The specific forming material, thickness, film forming condition, and the like are the same as those described in the first embodiment. The silicon oxide film 7 is also formed on the exposed surface of the land 5g in addition to the exposed surfaces of the sidewall cores 5d and the exposed surfaces of the silicon oxynitride film 4. After the silicon oxide film 7 is formed, the organic anti-reflection film 9a is formed. The specific forming material, thickness, film forming condition, and the like of the organic anti-reflection film 9a are the same as those described in the first embodiment. In this embodiment, the silicon-containing organic film 9b is not used. However, when it is necessary to enhance etching resistance in a step of using a photoresist as a mask, the silicon-containing organic film 9b may be used, as in the first and second embodiments.

Here, when the organic anti-reflection film 9a is used by a spin coating method, if a dark pattern portion spreading through a comparatively wide area, such as a land 5g, exists, the thickness (here, a height from the silicon oxynitride film 4) of the organic anti-reflection film 9a grows thick at a position corresponding to the dark pattern portion or its neighborhood. In this embodiment, such film thickness difference is prevented from occurring on the line-and-space pattern consisting of the openings 5c and the sidewall cores 5d since the dummy spaces 5f are provided at both X-directional ends of the memory cell array region 1A. That is, it is possible to prevent the organic anti-reflection film 9a from growing thick on the line-and-space pattern, especially, at areas peripheral to the memory cell array region 1A.

After the organic anti-reflection film 9a is formed, resist patterns 11 (mask patterns) are formed. As shown in FIGS. 50A and 50B, the resist patterns 11 are formed to cover the regions overlapping the silicon oxide film 7 formed in the inner side surface of the dummy core 5f in relation to a vertical direction and not to cover processed region 12. In FIG. 50A, a dotted line indicating the outer circumference of the process region 12 is illustrated so as to be slightly shifted from a solid line indicating the outer circumference of the resist pattern 11. However, the dotted line and the solid line are illustrated for facilitating easy understanding, but may actually overlap each other. The same is applied to the drawings illustrated below. The forming material, thickness, film forming condition, and the like of the resist pattern 11 are the same as the resist pattern 10 described in the first and second embodiments.

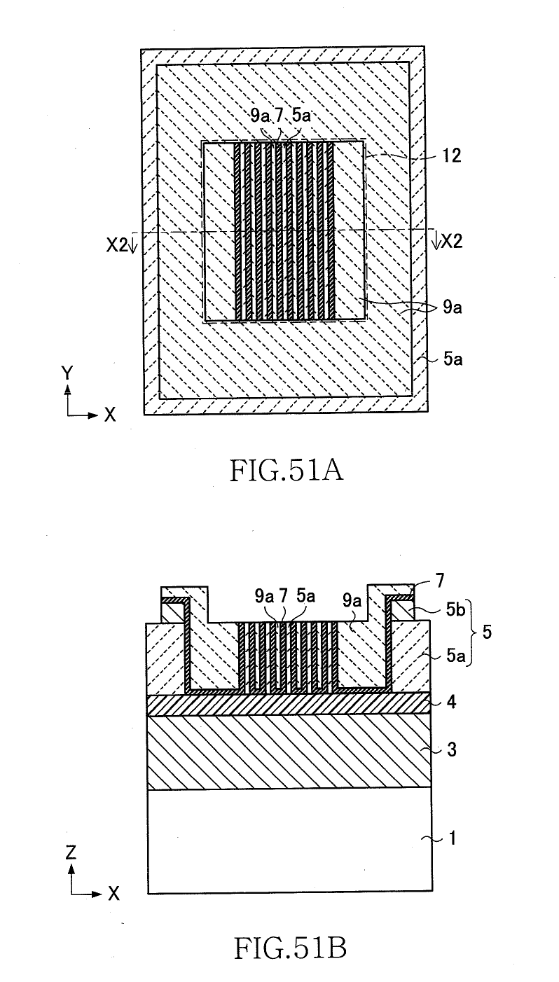

Next, as shown in FIGS. 51A and 51B, the organic anti-reflection film 9a is etched back using the resist patterns 11 as masks. This etching is performed under the condition that the etching rates of the silicon oxide film 7, the organic anti-reflection film 9a, and the silicon-containing organic film 5b are nearly the same as each other and the etching rates is sufficiently higher than the etching rate of the resist pattern 11. Thus, the organic anti-reflection film 9a, the silicon oxide film 7, and the silicon-containing organic film 5b are simultaneously etched and the silicon oxide film 7 is exposed to the surface in the processed region 12. On the other hand, the silicon oxide film 7 is not exposed to the surface in the region overlapping the resist pattern 11 when viewed in the vertical direction.

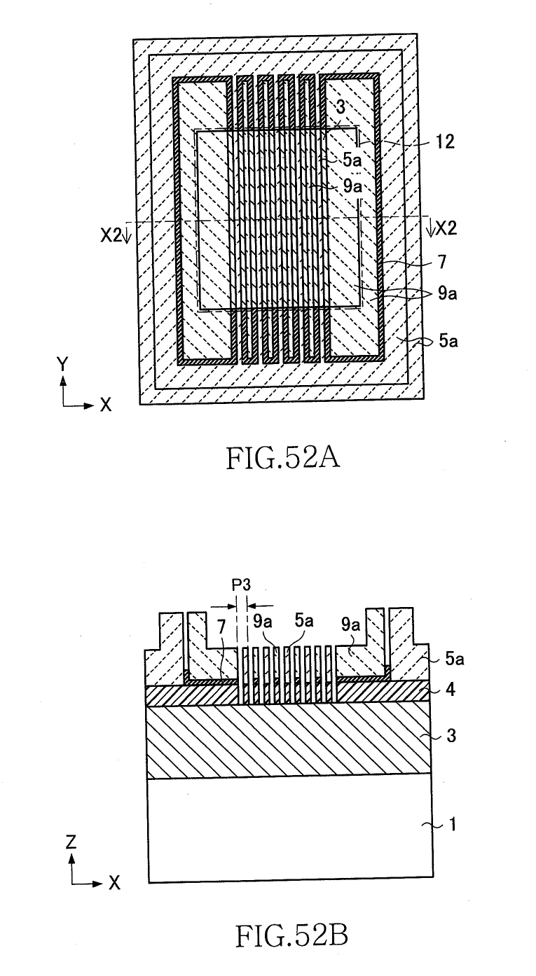

Next, as shown in FIGS. 52A and 52B, the silicon oxide film 7 is etched by dry etching. This etching is performed under the condition that etching selectivity is obtained with respect to the organic anti-reflection film 9a and the organic anti-reflection film 5a. The specific etching condition may be the same as the condition when the surface of the amorphous carbon film 3 is exposed in the second embodiment. In this etching, etched is also a part of the silicon oxynitride film 4 overlapping the sidewall spacer (the silicon oxide film 7 removed in this etching) in a vertical view. Thus, line-and-space pattern with a pitch of P3=50 nm is transferred onto the silicon oxynitride film 4.

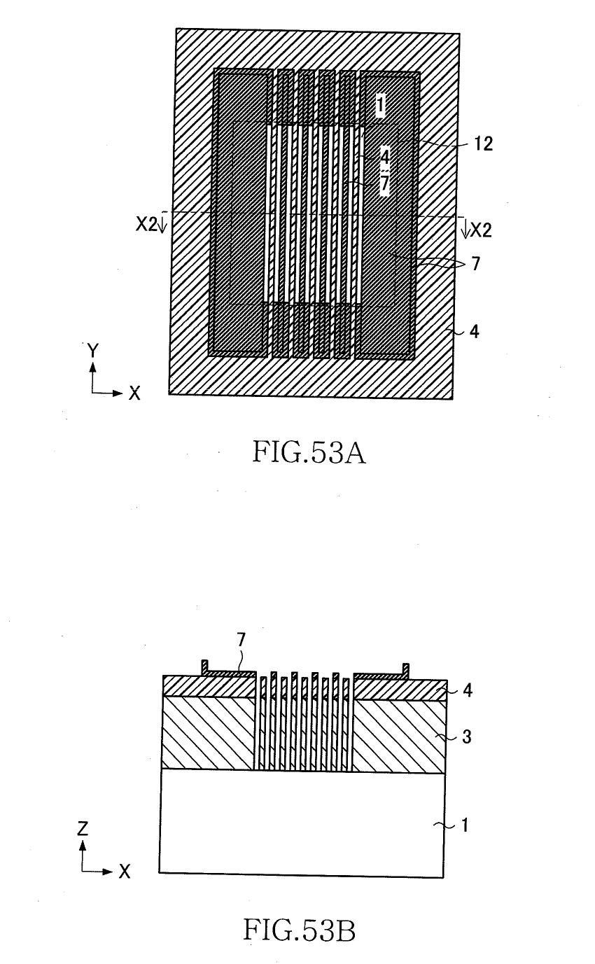

Next, as shown in FIGS. 53A and 53B, the line-and-space pattern is transferred onto the amorphous carbon film 3 by performing anisotropic dry etching using the silicon oxynitride film 4, onto which the line-and-space space is transferred, as a mask. At this time, the organic anti-reflection film 9a and the organic anti-reflection film 5a are removed together with the amorphous carbon film 3. The specific etching condition may be the same as the condition when the amorphous carbon film 3 is removed in the second embodiment.

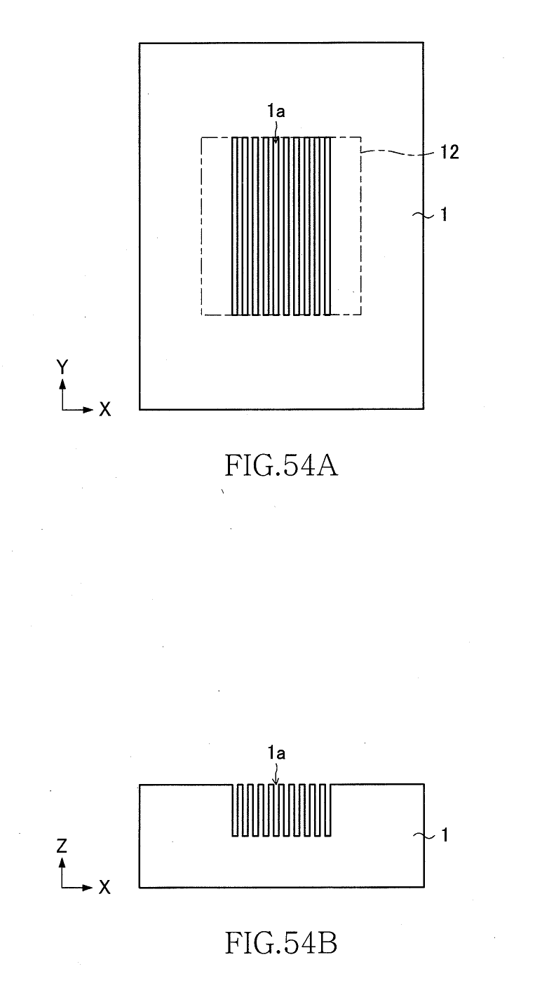

Next, as shown in FIGS. 54A and 54B, the silicon substrate 1 of the underlying substrate is etched by dry etching using the amorphous carbon film 3 as a mask. This etching is performed under the condition that the etching rates of the silicon substrate 1, the silicon oxynitride film 4, and the silicon oxide film 7 is sufficiently higher than the etching rate of the amorphous carbon film 3. Thus, the line-and-space pattern is transferred onto the region corresponding to the processed region 12 on the surface of the silicon substrate 1, and thus removed are the silicon oxide film and the silicon oxynitride film 4 formed on the amorphous carbon film 3.

Finally, as in the second embodiment, the amorphous carbon film 3 is removed using an oxygen gas by plasma asking. Thus, the trench pattern with double density of the minimum processing size is formed in the processed region 12.

According to the method of manufacturing the semiconductor device, as described above, it is possible to obtain the advantage that the peeling rarely occurs in the interface between the hard mask layer (the amorphous carbon film 3) and the member (the silicon substrate 1) to be etched. Moreover, it is possible to obtain the advantage of preventing the organic anti-reflection film 9a from growing thick on the line-and-space pattern, especially, at areas peripheral to the memory cell array region 1A by providing the dummy spaces 5f at both X-directional ends of the memory cell array region 1A.

When the silicon oxide film 7 is exposed inside the processed region 12, used is the resist pattern 11 which covers the region overlapping the silicon oxide film 7 formed in the inner side surface of the land 5g in a vertical view and does not cover the process region 12. Therefore, it is possible to make the silicon oxide film 7 remain in the region other than the processed region by the etching of the silicon oxide film 7. Accordingly, it is possible to prevent the trench pattern from being formed in the region other than the processed region 12.

As described above, the resist pattern 11 is formed immediately after the organic anti-reflection film 9a is formed. Therefore, it is possible to perform the process of making the silicon oxide film 7 remain in the region other than the processed region 12 and the process of forming the line-and-space pattern inside the processed region 12 at once. Accordingly, it is possible to form the desired trench pattern by a less number of steps.

It is apparent that the present invention is not limited to the above embodiments, but may be modified and changed without departing from the scope and spirit of the invention.

In the above-described embodiments, for example, used is the multi-layered resist film including the organic anti-reflection film, the silicon-containing organic film, and the normal photoresist film as a minute pattern forming a resist film. However, a single-layered resist film may be used.

In the above-described embodiments, a simple rectangular pattern is used as the core pattern. Even when a core pattern with an arbitrary shape is used, substantially the same processes can be performed. Even in this case, it is necessary to make the width of the sidewall spacer to be uniform.

In the above-described embodiments, the alignment monitor mark is used as the pattern used in the peripheral circuit region 1B. However, in the peripheral circuit region 1B, a pattern with an arbitrary size and an arbitrary shape may be formed without limiting the width of the pattern of the hard mask of the sidewall spacer.

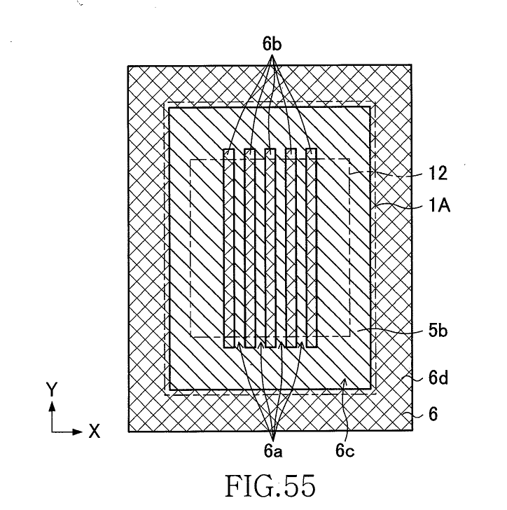

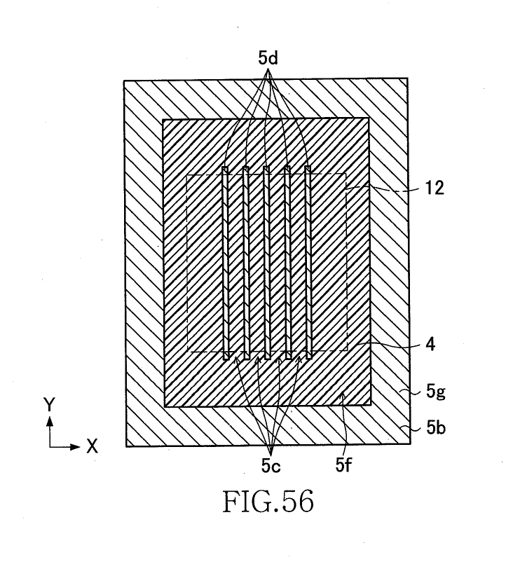

In the above-described third embodiment, the dummy spaces 5f are provided at both X-directional ends of the memory cell array region 1A. The dummy spaces 5f may be provided at both Y-directional sides of the memory cell array region 1A, too. FIG. 55 and FIG. 56 are plan views of the semiconductor device each corresponding to the FIG. 48A and FIG. 49A, respectively. FIG. 55 shows the resist pattern 6 to form such dummy spaces 5f. FIG. 56 shows the coating film 5 formed by the resist pattern 6 described in FIG. 55. Providing such dummy spaces 5f can minimize the variety of the thickness of a coating film along to the Y direction.

In the above-described third embodiment, one dummy space 5f is provided at each of both X-directional ends of the memory cell array region 1A. A plural of the dummy space 5f may be provided at each of both X-directional ends of the memory cell array region 1A. For example, each of the two dummy spaces 5f can be divided into multiple spaces. Providing a plural of the dummy space 5f arranged at the same pitch as the line-and-space pattern enables to obtain wide focal depth when the line-and-space pattern is formed. As a result, it becomes possible to obtain a good pattern formulation.

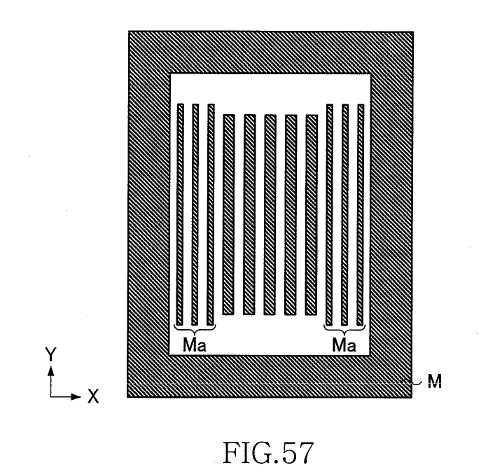

In case that a positive photoresist is used as a material of the resist pattern 6, anti-resolution adjunct dark pattern portions (portions which are not transferred onto the resist pattern 6) smaller than the resolution limit can be arranged in portions (light pattern portions) corresponding to the dummy spaces 6c in the photo mask used when the resist pattern 6 is patterned. FIG. 57 show a plan view of the photo mask M which has such anti-resolution adjunct dark pattern portions Ma. In the example described in FIG. 57, a plural of the linear type of the anti-resolution adjunct dark pattern portions Ma are arranged parallel to the line-and-space pattern for each of the dummy spaces 6c. This configuration enables to obtain wide focal depth when the line-and-space pattern is formed. As a result, it becomes possible to obtain a good pattern formulation.

In the above explanation, an example using the positive photoresist in relation to the third embodiment is explained. In case that a negative photoresist is used, the same effect can be achieved by reversing the dark and light, id est, replacing the space portion of the photo mask into a pattern portion. That is, the thickness of the coating film formed on the line-and-space pattern can be equalized by providing concave portions which does not contribute the pattern formulation in terms of results in areas adjacent to the line-and-space pattern.

What is claimed is:

1. A method of manufacturing a semiconductor device comprising:
forming a first coating film on a member to be etched;
forming a sidewall core by patterning the first coating film;
forming a first layer covering at least a side surface of the sidewall core;
forming a second coating film on the first layer;
forming an embedded mask covering a concave portion of the first layer by etching the second coating film; and
exposing a portion of the member to be etched that overlaps with neither the sidewall core nor the embedded mask by etching the first layer.

2. The method as claimed in claim 1, wherein the forming the first coating film includes spin-coating an organic anti-reflection film.

3. The method as claimed in claim 1, wherein the forming the second coating film includes spin-coating an organic anti-reflection film.

4. The method as claimed in claim 1, wherein the forming the first layer is performed by an ALD method.

5. The method as claimed in claim 1, wherein
the member to be etched comprises a lower hard mask and an upper hard mask, and
the exposing the member to be etched includes exposing the lower hard mask that overlaps with neither the sidewall core nor the embedded mask by etching the first layer and the upper hard mask.

6. The method as claimed in claim 5, wherein
the upper hard mask comprises a silicon oxide film, a silicon nitride film, or a mixed film thereof, and
the forming the first coating film includes forming the first coating film to be in contact with the upper hard mask.

7. The method as claimed in claim 6, wherein
the upper hard mask comprises a first upper hard mask which is located on the lower hard mask, and a second upper hard mask which is formed on the first upper hard mask and has an etching rate different from that of the first upper hard mask, and
the exposing of the member to be etched includes:
exposing a portion of the first upper hard mask that overlaps with neither the sidewall core nor the embedded mask without exposing the lower hard mask by etching the first layer and the second upper hard mask; and
exposing the lower hard mask by etching back the exposed first upper hard mask.

8. The method as claimed in claim 5, further comprising:
forming a third coating film on the member to be etched after exposing the member to be etched;
forming first and second patterns in a first region where the sidewall core is formed and in a second region where no sidewall core is formed, respectively, by patterning the third coating film;
exposing the lower hard mask by etching the upper hard mask using the first and second patterns as masks; and
etching the lower hard mask using the upper hard mask after removing the first and second patterns.

9. The method as claimed in claim 5, further comprising, after forming the second coating film and before forming the embedded mask:
forming first and second patterns in a first region where the sidewall core is formed and in a second region where no sidewall core is formed, respectively, by patterning the second coating film; and
exposing the first coating film by etching the first layer using the first and second patterns as masks,
wherein the embedded mask is formed by etching the first and second coating films after the first coating film is exposed.

10. The method as claimed in claim 8, wherein the first pattern covers all of processed regions without covering non-processed regions inside the first region.

11. The method as claimed in claim 10, wherein the forming the sidewall core comprises forming a plurality of line-shaped sidewall cores arranged in a second direction perpendicular to a first direction, each line-shaped sidewall cores extending in the first direction from the processed regions to the non-process regions in parallel with each other.

12. The method as claimed in claim 11, wherein a thickness of the first layer is substantially same as a width of the sidewall core in the second direction.

13. The method as claimed in claim 8, wherein the first region is a memory cell array region and the second region is a peripheral circuit region.

14. The method as claimed in claim 1, wherein the forming the sidewall core comprises:
forming a plurality of the sidewall cores which have a line shape and are arranged in parallel to each other in a first region; and
forming a land surrounding the first region, wherein
dummy spaces are provided at both ends of the first region in array direction of the plurality of the sidewall.

15. The method as claimed in claim 14, wherein
one or more adjunct patterns having a pattern width smaller than a resolution limit are provided in areas corresponding to the dummy spaces in the photo mask used when a resist pattern which is used to form the sidewall cores is patterned.

16. The method as claimed in claim 14, wherein
a width of the dummy space in the array direction is wider than the width of spaces between the sidewall cores in the array direction.

17. The method as claimed in claim 14, wherein
the dummy spaces are also provided at both ends of the first region in orthogonal direction to the array direction.

18. The method as claimed in claim 14, wherein
the first layer also covers an inner side surface of the land, and
the forming the embedded mask comprises:
forming a mask pattern covering a region, which overlaps with the first layer formed on the inner side surface of the land in a vertical view, and covering no processed region inside the first region; and
exposing the first layer inside the process region by etching back the second coating film using the mask pattern as a mask.
